(19) United States
(12) Patent Application Publication
(10) Pub. No.: US 2016/0284927 A1
(43) Pub. Date: Sep. 29, 2016

(54) METHOD OF MANUFACTURING SEMICONDUCTOR DEVICE PACKAGE SUCH AS LIGHT-EMITTING DIODE PACKAGE

(71) Applicant: SAMSUNG ELECTRONICS CO., LTD., Suwon-si (KR)

(72) Inventors: Hyuk-jin CHO, Seoul (KR); Kyoung-jun KIM, Yongin-si (KR); Dong-hoon LEE, Seoul (KR)

(73) Assignee: SAMSUNG ELECTRONICS CO., LTD., Suwon-si (KR)

(21) Appl. No.: 15/067,868

(22) Filed: Mar. 11, 2016

(30) Foreign Application Priority Data
Mar. 23, 2015 (KR) 10-2015-0040212

(51) Int. Cl. H01L 33/00; H01L 33/48

(52) U.S. Cl. CPC H01L 33/005; H01L 33/486; H01L 2933/0033

(57) ABSTRACT

Provided is a method of manufacturing a light-emitting diode (LED) package. The method includes: preparing a support structure on which a plurality of LED chips, each of which includes a semiconductor stack structure, and a light-transmissive material layer covering the plurality of LED chips are formed; mounting the support structure, on which the LED chips and the light-transmissive material layer are formed, on a cutting stage; and cutting the light-transmissive material layer, the semiconductor stack structure, and the support structure between the plurality of LED chips, by using a cutting device having a pattern blade on the cutting stage to singulate each of the individual LED packages.

### CROSS-REFERENCE TO THE RELATED APPLICATION

This application claims priority from Korean Patent Application No. 10-2015-0040212, filed on Mar. 23, 2015, in the Korean Intellectual Property Office, the disclosure of which is incorporated herein in its entirety by reference.

### BACKGROUND

Methods consistent with example embodiments of the inventive concept relate to manufacturing a semiconductor device package such as a light-emitting diode (LED) package, which may include a singulation process of separately singulating semiconductor chips such as LED chips.

A plurality of LED chips may be formed on a substrate. The LED chips may need to undergo a singulation process for separating the LED chips from one another.

A typical singulation process may be performed by cutting a substrate by a rotating sawing blade wheel. In the singulation process, the width of a sawing line on the substrate must be as small as possible so that a larger number of LED chips may be disposed on the substrate and the cost of production may reduce. In the singulation process, a sawing time must be reduced to improve productivity.

### SUMMARY

Example embodiments of the inventive concept provide a method of manufacturing a semiconductor device package such as an LED package, which may improve a process of singulating semiconductor chips to reduce the unit cost of production and improve productivity.

According to an aspect of an example embodiment, there is provided a method of manufacturing an LED package. The method may include: preparing a support structure on which a plurality of LED chips, each of which includes a semiconductor stack structure, and a light-transmissive material layer covering the plurality of LED chips are formed; mounting the support structure, on which the LED chips and the light-transmissive material layer are formed, on a cutting stage; and cutting the light-transmissive material layer, the semiconductor stack structure, and the support structure between the plurality of LED chips, by using a cutting device having a pattern blade on the cutting stage to singulate each of the individual LED packages.

The support structure may be a resin substrate. The resin substrate may be a silicone resin, an epoxy resin, or a mixture thereof. The light-transmissive material layer may be any one of a wavelength conversion layer and a lens layer. Each of the LED packages may be a chip scale package (CSP).

The pattern blade may include a plurality of blades that are patterned in any one of a widthwise direction and a lengthwise direction with respect to a top surface of the support substrate. The pattern blade may include a plurality of line blades, grating blades, or ring blades. A sectional shape of each of the blades included in the pattern blade may be a triangular shape, a square shape, or an elliptical shape.

According to an aspect of another example embodiment, there is provided a method of manufacturing an LED package. The method may include: mounting a stack of a support structure, a plurality of LED chips disposed on the support structure and a light-transmissive material layer covering the plurality of LED chips, on a cutting stage; and cutting the stack between the plurality of LED chips, by using a cutting device having a pattern blade on the cutting stage to singulate each of the LED packages.

The support structure may be a resin substrate on which a circuit pattern is formed. The above method may further include: preparing the plurality of LED chips; and forming the light-transmissive material layer on the LED chips.

The method may further include adhering an adhesive tape to a bottom surface of the support structure. The support structure to which the adhesive tape is adhered may be mounted on the cutting stage.

The pattern blade may include line blades or grating blades which are patterned in at least one of a widthwise direction and a lengthwise direction with respect to a top surface of the support structure. The line blades and grating blades may apply force to the light-transmissive material layer and the support structure in a direction perpendicular to the top surface of the support structure, and cut the light-transmissive material layer and the support structure.

The pattern blade may include a plurality of ring blades which are patterned in at least one of a widthwise direction and a lengthwise direction with respect to a top surface of the support structure. The ring blades may apply force to the light-transmissive material layer and the support structure in directions parallel to and perpendicular to the top surface of the support structure, and cut the light-transmissive material layer and the support structure.

According to an aspect of still another example embodiment, there is provided a method of manufacturing an LED package. The method may include: mounting a stack of a support structure, a semiconductor structure and an upper layer, which are stacked in this order, on a cutting stage; and cutting the stack by using a cutting device having a pattern blade on the cutting stage, to singulate a plurality of semiconductor device packages at the same time.

In the above method, the cutting the stack may include applying force in a direction perpendicular to the stack from a top surface of the upper layer. Here, the applying force may include applying force on boundaries of the plurality of semiconductor packages.

The pattern blade may include blades of any one type of line blades, grating blades, and ring blades.

The pattern blade may include a plurality of blades which are patterned in at least one of a widthwise direction and a lengthwise direction with respect to a top surface of the support substrate.

### BRIEF DESCRIPTION OF THE DRAWINGS

Example embodiments of the inventive concept will be more clearly understood from the following detailed description taken in conjunction with the accompanying drawings, in which:

FIG. 1 is a flowchart of a method of manufacturing a semiconductor light-emitting diode (LED) package, according to an example embodiment;

FIGS. 2A to 10 are cross-sectional views of a method of manufacturing an LED package, according to example embodiments;

FIG. 11 is a schematic plan view of a wafer on which a semiconductor stack structure shown in FIGS. 2A and 2Ba is formed, according to an example embodiment;

FIG. 12 is a cross-sectional view of an LED package manufactured by using a method of manufacturing an LED package, according to an example embodiment;

FIGS. 13A to 13C are diagrams for explaining a cutting stage and a cutting device used for a method of manufacturing an LED package, according to example embodiments;

FIGS. 14A and 14B each illustrate a plan view of a bottom of a pattern blade of a cutting device used for a method of manufacturing an LED package, according to example embodiments;

FIGS. 14C-14H each illustrate a cross-sectional view of each blade shape of a cutting device used for a method of manufacturing an LED package, according to example embodiments;

FIG. 15 is a cross-sectional view of a cutting method used for a method of manufacturing an LED package, according to an example embodiment;

FIGS. 16 to 19 are cross-sectional views of a method of manufacturing an LED package, according to example embodiments;

FIG. 20 is a flowchart of a method of manufacturing an LED package, according to an example embodiment;

FIGS. 21 to 23 are diagrams of a method of manufacturing an LED package, according to example embodiments;

FIGS. 24 to 26 are cross-sectional views having various structures, which may be manufactured by using the method of manufacturing the LED package shown in FIGS. 21 to 23, according to example embodiments;

FIG. 27 is a flowchart of a method of manufacturing an LED package, according to an example embodiment;

FIGS. 28 to 31 are diagrams of a method of manufacturing an LED package, according to example embodiments;

FIG. 32 is an exploded perspective view of an example of a backlight (BL) assembly including an LED package, according to an example embodiment;

FIG. 33 is a schematic diagram of a flat-panel illumination system including an LED array unit (or a light-emitting module) in which an LED package is arranged, according to an example embodiment;

FIG. 34 is a schematic diagram of a bulb-type lamp, which is an illumination system including an LED array unit (or a light-emitting module) in which an LED package is arranged, according to an example embodiment;

FIG. 35 is an international commission on illumination (CIE) chromaticity diagram of a complete radiator spectrum, which is applicable to an LED package, according to an example embodiment;

FIG. 36 is a diagram of an example of an LED package, according to an example embodiment;

FIG. 37 is a diagram of an example in which a lamp including an LED array unit and an LED module in which an LED package is arranged, is applied to a home-network, according to an example embodiment.

FIG. 38 is an exploded perspective view of a light-emitting system including an LED array unit and an LED module in which an LED package is arranged, according to an example embodiment; and

FIG. 39 is a schematic diagram of an example of a network system to which an LED package is applied, according to an example embodiment.

### DETAILED DESCRIPTION OF THE EXAMPLE EMBODIMENTS

As used herein, the term “and/or” includes any and all combinations of one or more of the associated listed items. Expressions such as “at least one of,” when preceding a list of elements, modify the entire list of elements and do not modify the individual elements of the list.

The inventive concept will now be described more fully hereinafter with reference to the accompanying drawings, in which example embodiments of the inventive concept are shown. This inventive concept may, however, be embodied in different forms and should not be construed as limited to the embodiments set forth herein. Rather, these embodiments are provided so that this disclosure is thorough and complete and fully conveys the scope of the inventive concept to one skilled in the art. In the drawings, the thicknesses of layers and regions are exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. Thus, a first element, component, region, layer or section discussed below could be termed a second element, component, region, layer or section without departing from the teachings of the inventive concept.

Spatially relative terms, such as “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The example embodiments of the inventive concept are described herein with reference to cross-section illustrations that are schematic illustrations of idealized embodiments of the inventive concept. As such, variations from the shapes of the illustrations as a result, for example, of manufacturing techniques and/or tolerances, are to be expected. Thus, the example embodiments of the inventive concept should not be construed as limited to the particular shapes of regions illustrated herein but are to include deviations in shapes that result, for example, from manufacturing. Not only the following embodiments are individually achieved as the inventive concept, but also the inventive concept is achieved by combining a plurality of embodiments as needed.

A method of manufacturing an LED package as described below may include various manufacturing operations. Here, although only necessary manufacturing operations are provided as examples, the inventive concept is not limited thereto.

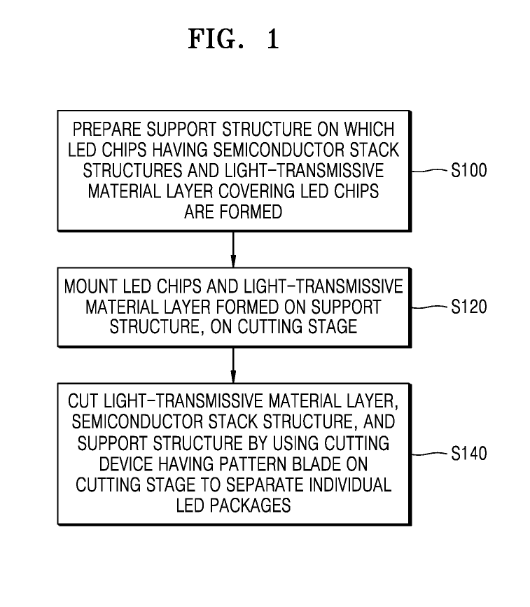

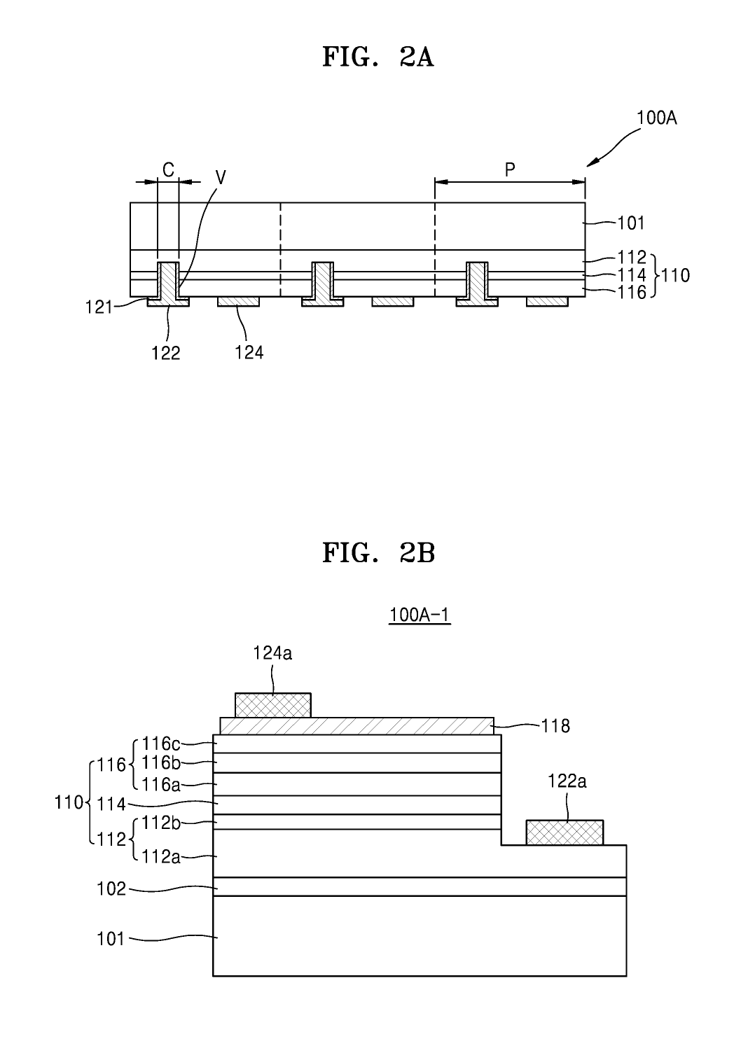

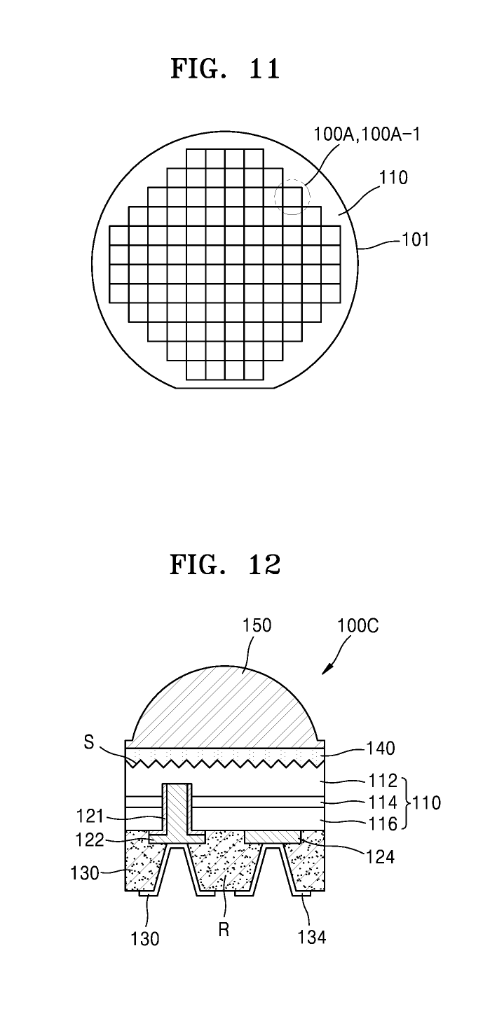

FIG. 1 is a flowchart of a method of manufacturing an LED package, according to an example embodiment of the inventive concept. FIGS. 2A to 10 are cross-sectional views of a method of manufacturing an LED package, according to an example embodiment of the inventive concept. FIG. 11 is a schematic plan view of a wafer on which a semiconductor structure or semiconductor stack structure shown in FIGS. 2A and 2B is formed.

Initially, a method of manufacturing an LED package according to an example embodiment will be described with reference to FIGS. 2A to 11. FIGS. 2A to 11 illustrate an example of a chip-scale package (CSP), but the inventive concept is not limited thereto. The method of manufacturing an LED package may start from an operation of preparing a wafer 101 on which a semiconductor stack structure 110 is formed. FIGS. 2A and 2B illustrate an example of the wafer 101 on which the semiconductor stack structure 110 is formed, but the inventive concept is not limited thereto.

Referring to FIG. 2A, the semiconductor stack structure 110 may be an epitaxial layer formed on the wafer 101 to embody an LED chip 100A. The semiconductor stack structure 110 may include a first semiconductor layer 112, an active layer 114, and a second semiconductor layer 116. As shown in FIG. 11, the semiconductor stack structure 110 for an LED chip 100A or 100A-1 may be formed on the wafer 101.

An insulating substrate, a conductive substrate, or a semiconductor substrate may be used as the wafer 101 as needed. For example, the wafer 101 may include sapphire, SiC, Si, MgAl2O4, MgO, LiAlO2, LiGaO2, GaN, or SiAl. The semiconductor stack structure 110 may include a Group-III nitride semiconductor. For example, each of the first and second semiconductor layers 112 and 116 may be a nitride layer having a composition of AlxInyGa1−x−yN (0≦x≦1, 0≦y≦1, and 0≦x+y≦1), but is not limited thereto. Each of the first and second semiconductor layers 112 and 116 may include a material, such as an AlGaInP-based semiconductor or an AlGaAs-based semiconductor.

The first and second semiconductor layers 112 and 116 may include semiconductors doped with an n-type dopant and a p-type dopant, respectively. The n-type dopant may be Si, and the p-type dopant may be Mg. Conversely, the first and second semiconductor layers 112 and 116 may be p-type and n-type semiconductor layers, respectively. The active layer 114 disposed between the first and second semiconductor layers 112 and 116 may have a multi-quantum well (MQW) structure in which quantum well layers and quantum barrier layers are alternately stacked. For example, when the active layer 114 includes a nitride semiconductor, the active layer 114 may have a GaN/InGaN structure. Alternatively, the active layer 114 may have a single-quantum well (SQW) structure. First and second electrodes 122 and 124 may be respectively connected to the first and second semiconductor layers 112 and 116. The first and second electrodes 122 and 124 may be provided in each individual LED chip 100A.

In the present embodiment, the first electrode 122 may be formed by using a via V connected to the first semiconductor layer 112. An insulating layer 121 may be formed within the via V and on a portion of the surface of the semiconductor stack structure 110 to prevent the first electrode 122 from being undesirably connected to the active layer 114 and the second semiconductor layer 116. Thus, the present embodiment is a case in which one first electrode 122 and one second electrode 124 are formed on the same surface of the LED chip 100A. However, only an electrode having one polarity may be provided on one surface of the LED chip 100A or at least two electrodes having at least one polarity may be provided according to a structure of the LED chip 100A.

A contact region C of the first semiconductor layer 112 may be exposed by the via V, and a partial region of the first electrode 122 may contact the contact region C through the via V. Thus, the first electrode 122 may be connected to the first semiconductor layer 112.

The number, shape, and pitch of vias V and a diameter of the via V contacting the first semiconductor layer 112 (or contact area between the via V and the first semiconductor layer 112) may be appropriately adjusted to reduce a contact resistance. The vias V may be arranged in rows and columns in various shapes to improve the flow of current. The number of vias V and the contact area may be adjusted such that an area of the contact region C ranges from about 0.1% to about 20% (for example, about 0.5% to about 15%, and more specifically, about 1% to about 10%) of a planar area P of the semiconductor stack structure 110. For example, if the area of the contact region C is less than about 0.1% of the planar area P of the semiconductor stack structure 110, current spreading may not be uniform, thereby to degrade emission characteristics. Otherwise, if the area of the contact region C is greater than about 20% of the planar area P of the semiconductor stack structure 110, an emission area may reduce, thereby to degrade emission characteristics and luminance.

For example, the diameter of the via V contacting the first semiconductor layer 112 may range from about 1 μm to about 50 μm, and the number of vias V may range from 1 to 48000 per area of the semiconductor stack structure 110 according to a width of the semiconductor stack structure 110. Although the number of vias V depends on the width of the semiconductor stack structure 110, the number of vias V may range from, for example, 2 to 45000, specifically, 5 to 40000, and more specifically, 10 to 35000. The vias V may be arranged in a matrix form in rows and columns such that a distance between the vias V ranges from about 10 μm to about 1000 μm, for example, about 50 μm to about 700 μm, specifically, about 100 μm to about 500 μm, and more specifically, about 150 μm to about 400 μm.

If the distance between the vias V is less than about 10 μm, the number of vias V may increase, and an emission area may reduce, thereby to degrade luminous efficiency. The vias V may be formed to a different depth according to thicknesses of the second semiconductor layer 116 and the active layer 114. For example, the depth of the vias V may range from about 0.1 μm to about 5.0 μm. Each of the first and second electrodes 122 and 124 may include a material, such as silver (Ag), nickel (Ni), aluminum (Al), rhodium (Rh), palladium (Pd), iridium (Jr), ruthenium (Ru), magnesium (Mg), zinc (Zn), platinum (Pt), or gold (Au) and have a single layer structure or a structure including at least two layers.

FIG. 2B is a cross-sectional view of an LED chip 100A-1 according to another example embodiment.

Specifically, FIG. 2B illustrates only one LED chip 100A-1 of the inventive concept for brevity of description. The LED chip 100A-1 may include a wafer 101 and a first semiconductor layer 112, an active layer 114, and a second semiconductor layer 116, which may be sequentially disposed on the wafer 101. As described above, the first semiconductor layer 112, the active layer 114, and the second semiconductor layer 116 may constitute a semiconductor stack structure 110. A material forming the wafer 101 may be as described above.

A buffer layer 102 may be disposed between the wafer 101 and the first semiconductor layer 112. The buffer layer 102 may include InₓAl_{y}Ga_{1-x-y}N (0≦x≦1 and 0≦y≦1). For example, the buffer layer 102 may include at least one of GaN, AN, AlGaN, and InGaN. When necessary, the buffer layer 102 may be formed by combining a plurality of layers or gradually changing the compositions of layers.

As described above, the first semiconductor layer 112 may be a nitride layer that satisfies an n-type AlₓIn_{y}Ga_{1-x-y}N (0≦x≦1, 0≦y≦1, and 0≦x+y≦1), and an n-type dopant may be Si. For example, the first semiconductor layer 112 may include n-type GaN.

In the present embodiment, the first semiconductor layer 112 may include a first semiconductor contact layer 112a and a current diffusion layer 112b. A dopant concentration of the first semiconductor contact layer 112a may range from 2×10¹⁸ cm⁻³ to 9×10¹⁹ cm⁻³. The first semiconductor contact layer 112a may have a thickness of about 1 μm to about 5 μm. The current diffusion layer 112b may have a structure formed by repetitively stacking a plurality of InₓAl_{y}Ga_{1-x-y}N (0≦x, y≦1, 0≦x+y≦1) layers having different compositions or different dopant concentrations. For example, the current diffusion layer 112b may be an n-type superlattice layer formed by repetitively stacking an n-type GaN layer having a thickness of about 1 nm to about 500 nm and/or at least two AlₓIn_{y}Ga_{z}N (0≦x, y, z≦1, except x=y=z=0) layers having different compositions. The current diffusion layer 112b may have a dopant concentration of about 2×10¹⁸ cm⁻³ to about 9×10¹⁹ cm⁻³. When necessary, the current diffusion layer 112b may further include an insulating material layer.

As described above, the second semiconductor layer 116 may be a nitride layer that satisfies a p-type AlₓIn_{y}GaN (0≦x≦1, 0≦y≦1, and 0≦x+y≦1), and a p-type dopant may be Mg. For example, although the second semiconductor layer 116 may have a single layer structure, the second semiconductor layer 116 may also have a multi-layered structure having different compositions as in the present embodiment.

The second semiconductor layer 116 may include an electron blocking layer (EBL) 116a, a low-concentration p-type GaN layer 116b, and a high-concentration p-type GaN layer 116c serving as a contact layer. For example, the EBL 116a may be a single layer formed of Al_{y}Ga_{1-y}N or have a structure formed by stacking a plurality of InₓAl_{y}Ga_{1-x-y}N layers having different compositions, each of which has a thickness of about 5 nm to about 100 nm. An energy bandgap Eg of the EBL 116a may reduce away from the active layer 114. That is, the farther distance away from the active layer 114, the more reduced the energy bandgap Eg may be in the EBL 116a. For example, an Al content of the EBL 116a may reduce away from the active layer 114.

As described above, the active layer 114 may have a multiple quantum well (MQW) structure in which a quantum well layer and a quantum barrier layer are alternately stacked. For example, the quantum well layer and the quantum barrier layer may include InₓAl_{y}Ga_{1-x-y}N (0≦x≦1, 0≦y≦1, and 0≦x+y≦1) having different compositions. In a specific example, the quantum well layer may be formed of InₓGa₁₋ₓN (0<x≦1), and the quantum barrier layer may be formed of GaN or AlGaN. Each of the quantum well layer and the quantum barrier layer may have a thickness of about 1 nm to about 50 nm. The active layer 114 is not limited to an MQW structure and may have an SQW structure.

The LED chip 100A-1 may include a first electrode 122a disposed on the first semiconductor layer 112, and an ohmic contact layer 118 and a second electrode 124a that are sequentially disposed on the second semiconductor layer 116. The first electrode 122a may include, but is not limited to, Ag, Ni, Al, Cr, Rh, Pd, Jr, Ru, Mg, Zn, Pt, or Au, and have a single layer structure or a structure including at least two layers. A pad electrode layer (not shown) may be further disposed on the first electrode 122a. The pad electrode layer may include at least one of Au, Ni, and Sn.

The ohmic contact layer 118 may be variously embodied according to a chip structure. For example, when the ohmic contact layer 118 has a flip-chip structure, the ohmic contact layer 118 may include a metal, such as silver (Ag), gold (Au), or aluminum (Al), or a transparent conductive oxide (TCO), such as indium tin oxide (ITO), zinc indium oxide (ZIO), or gallium indium oxide (GIO). In a reversely disposed structure, the ohmic contact layer 118 may include a light-transmissive electrode. The light-transmissive electrode may be a TCO layer or a nitride layer. For example, the ohmic contact layer 118 may be formed of at least one selected from the group consisting of ITO, zinc-doped indium tin oxide (ZITO), ZIO, GIO, zinc tin oxide (ZTO), fluorine-doped tin oxide (FTO), aluminum-doped zinc oxide (AZO), gallium-doped zinc oxide (GZO), In₄Sn₃O₁₂, and zinc magnesium oxide (Zn₍₁₋ₓ₎MgₓO, 0≦x≦1). When necessary, the ohmic contact layer 118 may include graphene. The second electrode 124b may include at least one of Al, Au, Cr, Ni, Ti, and Sn.

Hereinafter, a method of manufacturing an LED package will be described for brevity of description with reference to FIG. 2A.

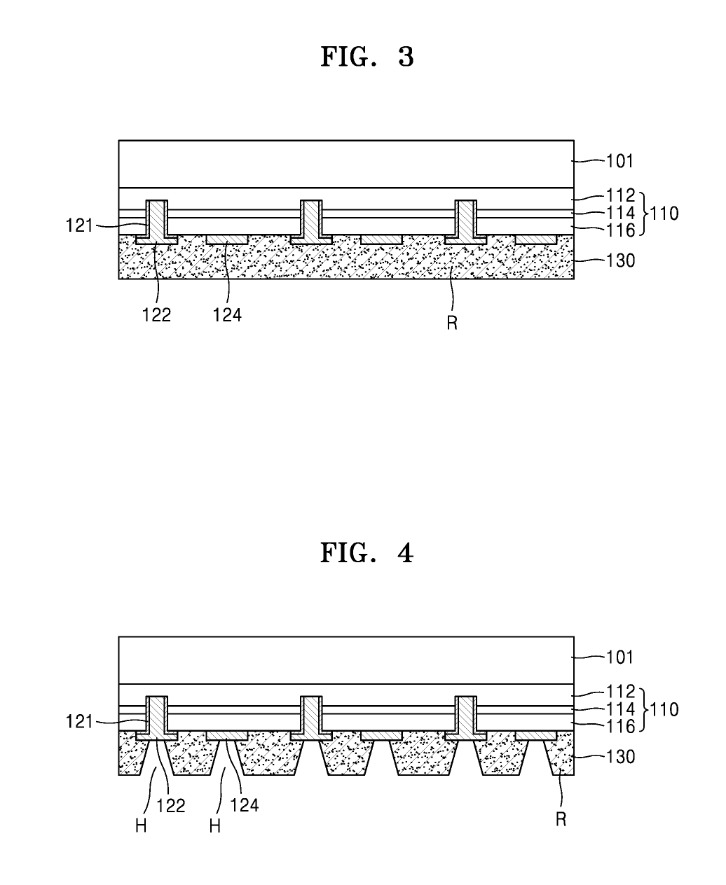

Referring to FIG. 3, a support structure 130 may be formed on a surface of the semiconductor stack structure 110 on which the first and second electrodes 122 and 124 are disposed. The support structure 130 may be a substrate for supporting the semiconductor stack structure 110. The support structure 130 may include a resin containing high-reflective powder R.

The high-reflective powder R may be metal powder or ceramic powder having high reflectivity. The high-reflective ceramic powder may include at least one selected from the group consisting of TiO₂, Al₂O₃, Nb₂O₅, and ZnO. The high-reflective metal powder may include at least one selected from Al and Ag. The high-reflective metal powder may be appropriately contained in the support structure 130 in such a range as to maintain the support structure 130 as an insulating material, thereby increasing a reflection rate of the support structure 130.

The support structure 130 may include a curing resin or a semi-curing resin. The curing resin may be a resin that remains flowable before a curing process, and may be cured when energy, such as heat or ultraviolet (UV) light, is applied thereto. The curing resin may be resin that is formed by coating a liquid resin by using various coating processes, for example, a spin coating process, a screen process, an inkjet printing process, or a dispensing process, and curing the coated liquid resin.

The semi-curing resin may be formed by adhering a semi-cured resin structure to a surface on which an electrode is formed. The term “semi-curing” refers to a state in which a resin structure is not completely cured but cured to an extent that it can be easily handled and processed. The semi-cured resin structure may be bonded under pressure at an appropriate temperature to the surface of the semiconductor stack structure 110.

The support structure 130 may have an electrical insulating characteristic to easily form, in the supporting structure 130, a connection electrode that connects to an external circuit. The support structure 130 may be formed of a silicone resin, an epoxy resin, or a mixture thereof.

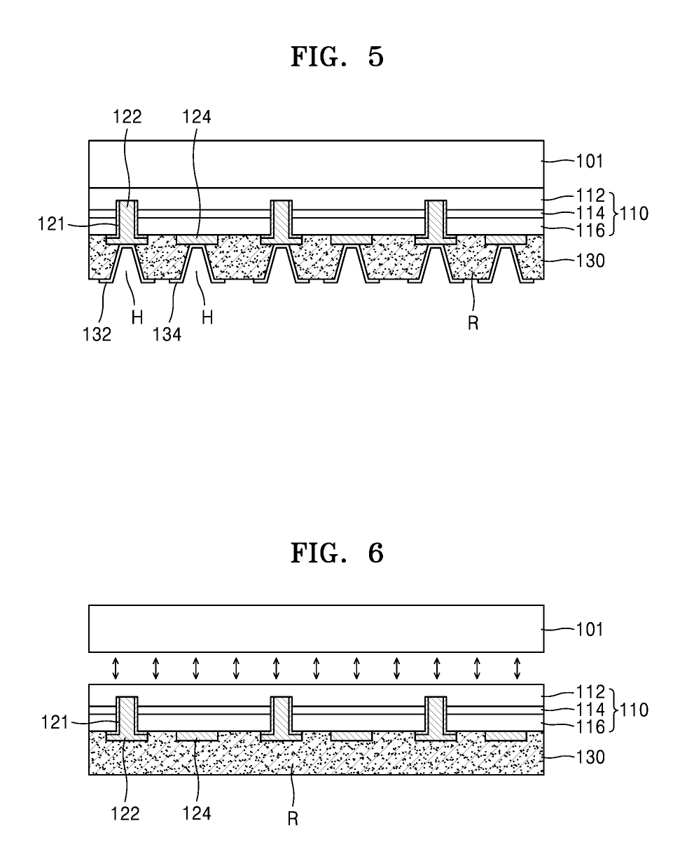

Referring to FIGS. 4 and 5, a process of forming connection electrodes 132 and 134 to be connected to an external circuit may be performed on the support structure 130. As shown in FIG. 4, through holes H may be formed in the support structure 130 until the first and second electrodes 122 and 124 are exposed. The through holes H may be formed by using an etching process, such as a reactive ion etching (RIE) process, or laser and mechanical drilling processes. The through holes H may be formed in regions in which the connection electrodes 132 and 134 will be formed, thereby exposing the first and second electrodes 122 and 124.

As shown in FIG. 5, the first and second connection electrodes 132 and 134 may be formed on the support structure 130 and respectively connected to the portions of the first and second electrodes 122 and 124 that are exposed by the through holes H. The first and second connection electrodes 132 and 134 may extend from the exposed portions of the first and second electrodes 122 and 124 along the through holes H to a partial region of a bottom surface of the support structure 130 so that the first and second connection electrodes 132 and 134 may be connected to an external circuit on the bottom surface of the support structure 130. The first and second connection electrodes 132 and 134 may be formed by forming a seed layer by using Ni or Cr and forming an electrode material, such as Au, by using a plating process.

FIGS. 3 to 5 illustrate an example in which after the support structure 130 is formed, the connection electrodes 132 and 134 are formed through the through holes H. However, the order of operations to form the connection electrodes 132 and 134 may be changed. For example, after the first and second electrodes 122 and 124 and/or bumper extension electrodes (or connection electrodes) are previously formed to a thickness equal to that of the support structure 130, a resin support structure of silicon, epoxy, or polymer may be formed, and the bumper extension electrodes may be exposed by using a grinding process, a cutting process, or an etching process.

Referring to FIG. 6, the wafer 101 used as a growth substrate may be separated from the semiconductor stack structure 110. The wafer 101 may be separated from the semiconductor stack structure 110 by using a laser lift-off process. However, the inventive concept is not limited thereto, and the wafer 101 may be removed by using a mechanical or chemical etching process. Although the following embodiments will mainly describe a process of removing the wafer 101, the process of removing the wafer 101 may be omitted.

The present embodiment describes an example in which after the support structure 130 is formed and the connection electrodes 132 and 134 are formed, the wafer 101 is removed from the semiconductor stack structure 110. However, in another case, the process of removing the wafer 101 may be performed during any time after the support structure 130 is formed. For example, the process of removing the wafer 101 may be performed before the connection electrodes 132 and 134 are formed or before the through holes H for forming the connection electrodes 132 and 134 are formed.

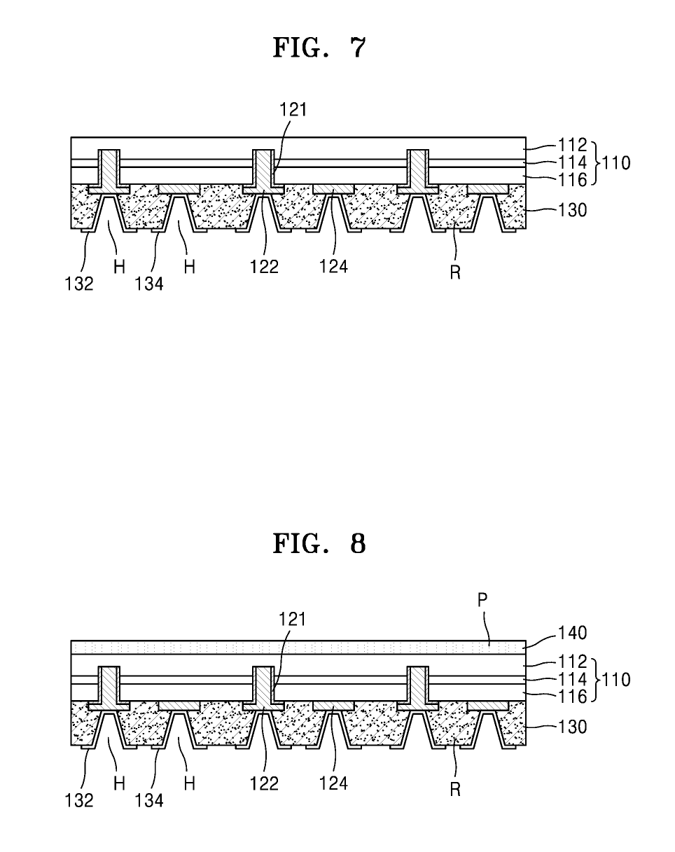

FIG. 7 illustrates the semiconductor stack structure 110 from which the wafer 101 is removed. As shown in FIG. 8, a wavelength conversion layer 140 serving as a light-transmissive material layer may be formed on a surface of the semiconductor stack structure 110 from which the wafer 101 is removed. The wavelength conversion layer 140 may be a phosphor layer. The wavelength conversion layer 140 may be a resin layer containing a wavelength conversion material P, such as quantum dots (QDs). The wavelength conversion layer 140 may be excited by light emitted by the active layer 114 and convert at least part of the light into light having a different wavelength. The wavelength conversion material P may include at least two materials that provide light having different wavelengths. The light converted by the wavelength conversion layer 140 may be combined with light generated by the active layer 114 to output white light. In another embodiment, the wafer 101 may not be removed, and the wavelength conversion layer 140 may be formed on the surface of the wafer 101.

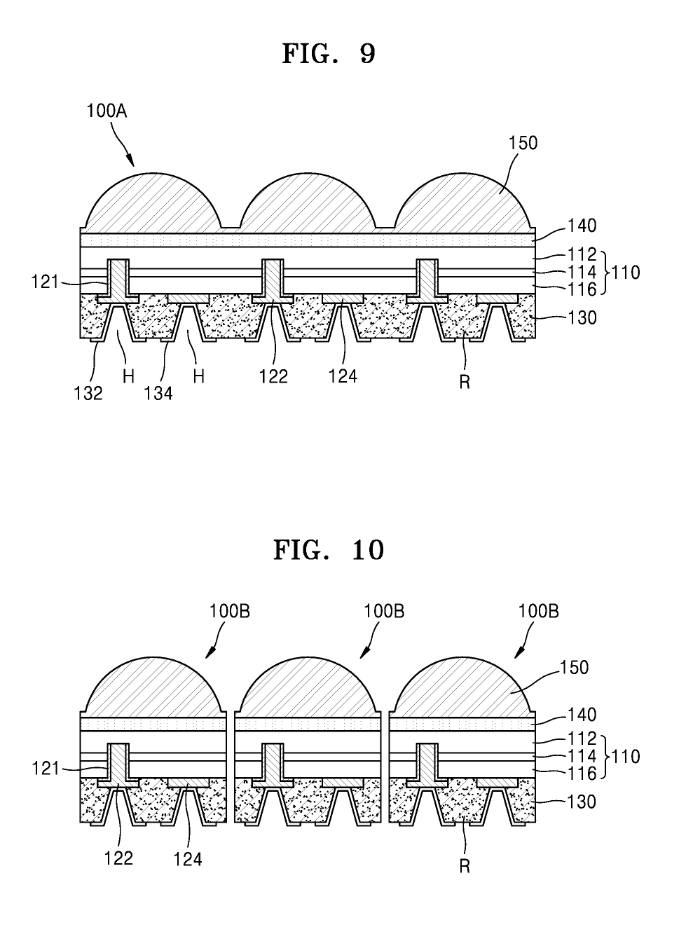

Referring to FIGS. 9 and 10, a lens layer 150 serving as a light-transmissive material may be formed on the wavelength conversion layer 140. Although the present embodiment describes an example in which the lens layer 150 is a convex lens serving as an optical member, various structures capable of changing a direction angle may be adopted. When necessary, the wavelength conversion layer 140 may not be formed, and the lens layer 150 may be directly formed on a surface of the semiconductor stack structure 110 from which the wafer 101 is removed.

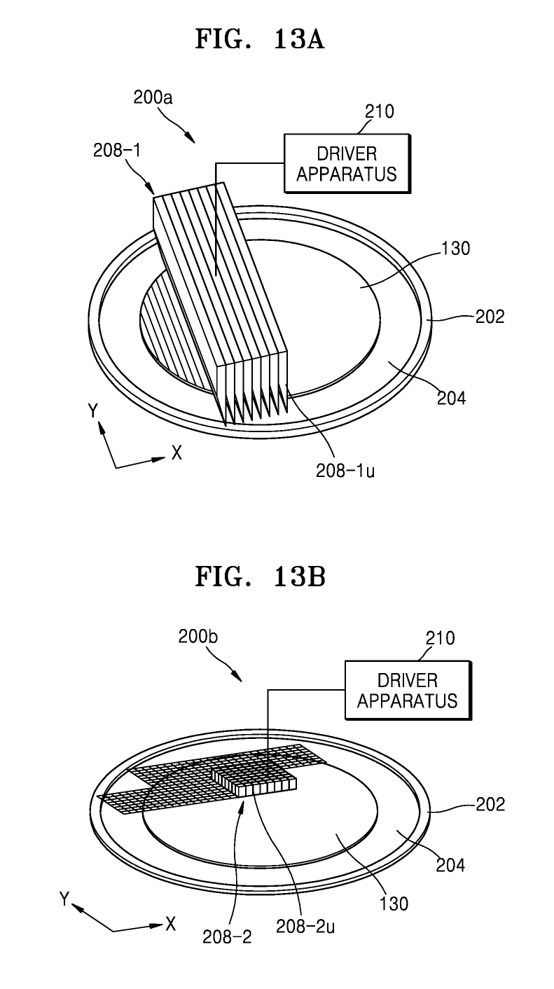

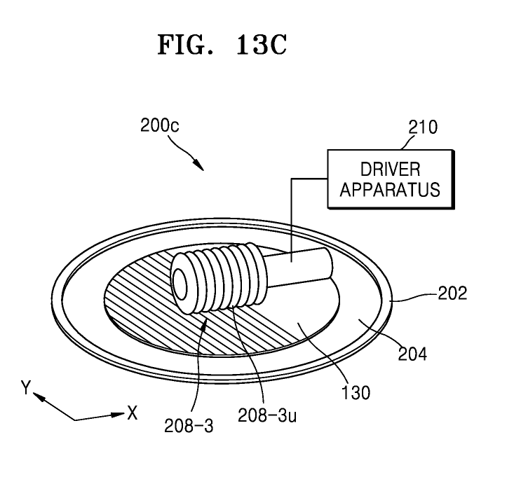

Subsequently, as shown in FIGS. 13A to 13C, the LED chips 100A (including the semiconductor stack structure 110), the lens layer 150, and the wavelength conversion layer 140 formed on the support structure 130 may be mounted on a cutting stage 202. As described above, the wavelength conversion layer 140 and the lens layer 150 may constitute a light-transmissive material layer.

The lens layer 150, the wavelength conversion layer 140, the semiconductor stack structure 110, and the support structure 130 may be singulated (or separated) along boundaries distinguishing a plurality of LED chips 100A from one another by using a cutting process on the cutting stage (refer 202 in FIGS. 13A to 13C), thereby forming individual LED packages 100B. As shown in FIGS. 13A to 13C, in the above-described singulation (or separation) process, the lens layer 150, the wavelength conversion layer 140, the semiconductor stack structure 110, and the support structure 130 may be cut by using cutting devices 200a and 200b having pattern blades 208-1 and 208-2. Hereinafter, for brevity of description, the pattern blades 208-1 and 208-2 will be inclusively referred to as a pattern blade 208, and the cutting devices 200a and 200b will be inclusively referred to as a cutting device 200.

The above-described singulation process may not be a sawing process by using a typical sawing blade wheel but a cutting process by using the pattern blade 208. Merits of the cutting process will be described later.

As described above, respective process operations of the method of manufacturing an LED package may be described with reference to the flowchart of FIG. 1. The method of manufacturing an LED package may include preparing a support structure 130 on which LED chips 100A having an semiconductor stack structure 110 and light-transmissive material layers, namely, the wavelength conversion layer 140 and the lens layer 150, covering the LED chips 100A are formed (step S100).

Thereafter, the LED chips 100A formed on the support structure 130 and, namely, the wavelength conversion layer 140 and the lens layer 150, may be mounted on the cutting stage (refer to 202 in FIGS. 13A to 13C) (step S120).

Subsequently, the light-transmissive material layers, namely, the wavelength conversion layer 140 and the lens layer 150, the semiconductor stack structure 110, and the support structure 130 may be cut along boundaries distinguishing the plurality of LED chips A from one another on the cutting stage by using a cutting device 200 having the pattern blade 208 (refer to 202 in FIGS. 13A to 13C), thereby singulating (or separating) individual LED packages 100B from one another (step S140).

FIG. 12 is a cross-sectional view of an LED package that may be manufactured by using the above-described method of manufacturing an LED package, according to an example embodiment.

Specifically, the LED package formed by the method of manufacturing the LED package, according to the present example embodiment, may have various structures. For example, an LED package 100C may have a similar structure to the LED package 100B shown in FIG. 10A except that a rough portion S is provided on a surface of a semiconductor stack structure 110 on which a wavelength conversion layer 140 is formed.

The rough portion S may effectively extract light from the semiconductor stack structure 110 to improve optical efficiency. The rough portion S may be formed by etching the surface of the semiconductor stack structure 110 after the wafer 101 is removed or during the removal of the wafer 101. In a structure from which the wafer 101 is not removed, the rough portion S may be formed on the surface of the wafer 101, and the wavelength conversion layer 140, and/or a lens layer 150 may be stacked thereon.

FIGS. 13A to 13C are diagrams for explaining a cutting stage and a cutting device used for a method of manufacturing an LED package, according to an example embodiment.

Specifically, as described above with reference to FIGS. 2A to 9, FIGS. 13A to 13C illustrate an example in which a support structure 130 supporting the LED chips 100A, a lens layer 150, and a wavelength conversion layer 140 is mounted on a cutting stage 202. In FIGS. 13A to 13C, the LED chips 100A, the lens layer 150, and the wavelength conversion layer 140 described above with reference to FIGS. 2A to 9 are not illustrated for brevity of description. When necessary, an adhesive tape 204 may be adhered to a bottom surface of the support structure 130.

The adhesive tape 204 may be an ultraviolet (UV) tape or a thermosetting tape. The adhesive tape 204 may have a thickness of about 50 μm to about 200 μm. The adhesive tape 204 may be referred to as a dicing tape.

FIGS. 13A to 13C illustrate a process of cutting the support structure 130 mounted on the cutting stage 202 by using cutting devices 200a, 200b, and 200c having pattern blades 208-1, 208-2, and 208-3. The cutting devices 200a, 200b, and 200c may include the pattern blades 208-1, 208-2, and 208-3 and a driver apparatus 210 configured to drive the pattern blades 208-1, 208-2, and 208-3.

While the driver apparatus 210 moves the pattern blades 208-1, 208-2, and 208-3 in a widthwise direction (X direction) and a lengthwise direction (Y direction) on a top surface of the support structure 130, the support structure 130 may be mechanically cut. The pattern blades 208-1, 208-2, and 208-3 may respectively include a plurality of blades, namely, line blades 208-1u, grating blades 208-2u, and ring blades 208-3u, which may be patterned on the top surface of the support structure 130 in any one of the widthwise direction and the lengthwise direction.

As shown in FIG. 13A, the pattern blade 208-1 may include the plurality of line blades 208-1u, which may be applied to the top surface of the support structure 130 in a widthwise direction (X direction) or a lengthwise direction (Y direction). For brevity of description, the pattern blade 208-1 of FIG. 13A includes only the line blades 208-1u formed in the lengthwise direction. The line blades 208-1u may cut the support structure 130 at one time by applying force in a direction perpendicular to the top surface of the support structure 130.

As shown in FIG. 13B, the pattern blade 208-2 may include the plurality of grating blades 208-2u, which may be patterned in the widthwise direction (X direction) and the lengthwise direction (Y direction) with respect to the top surface of the support structure 130. The grating blades 208-2u may cut the support structure 130 at one time by applying force in the direction perpendicular to the top surface of the support structure 130.

As shown in FIG. 13C, the pattern blade 208-3 may include the plurality of ring blades 208-3u, which may be applied to the top surface of the support structure 130 in the widthwise direction (X direction) or the lengthwise direction (Y direction). For brevity of description, the pattern blade 208-3 of FIG. 13C includes only the ring blades 208-3u formed in the lengthwise direction. The ring blades 208-3u may cut the support structure 130 at one time by applying force in a rotation directions, that is, directions parallel and perpendicular to the top surface of the support structure 130.

Thus, when the pattern blades 208-1, 208-2, and 208-3 are used, a plurality of LED packages may be obtained by cutting the support structure 130 at one time, thereby improving productivity.

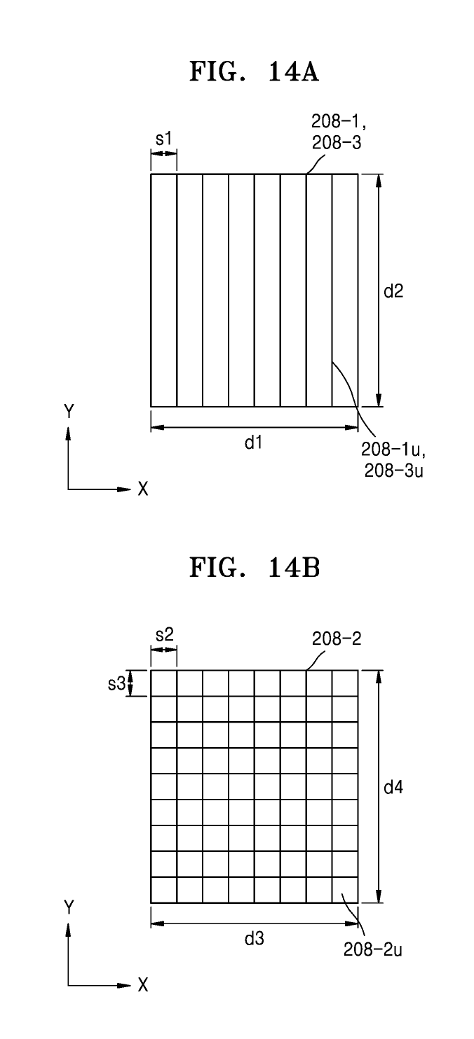

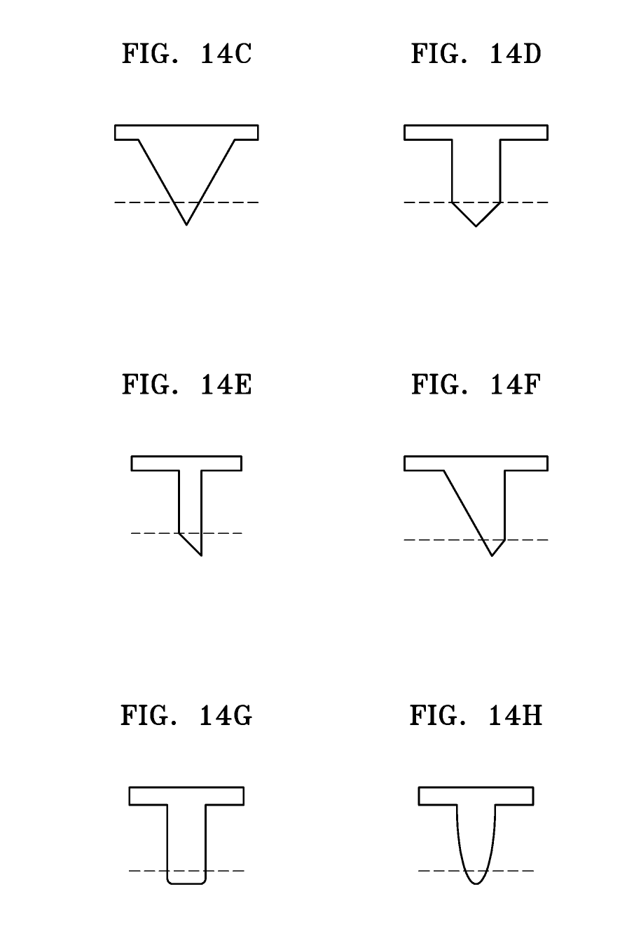

FIGS. 14A and 14B each illustrate a plan view of a bottom of a pattern blade of a cutting device used for the above-described method of manufacturing an LED package, according to example embodiments, and FIGS. 14C-14H each illustrates a cross-sectional view of each blade shape of a cutting device used for the above-described method of manufacturing an LED package, according to example embodiments.

Specifically, FIG. 14A may correspond to the pattern blades 208-1 and 208-3 of FIGS. 13A and 13C. That is, the pattern blades 208-1 and 208-3 may include a plurality of line blades 208-1u and a plurality of ring blades 208-3u formed in a widthwise direction (X direction) or a lengthwise direction (Y direction). FIG. 14B may correspond to the pattern blade 208-2 of FIG. 13B. That is, the pattern blade 208-2 may include grating blades 208-2u patterned in the widthwise direction (X direction) and the lengthwise direction (Y direction) with respect to the top surface of the support structure 130.

Each of the intervals s1, s2, and s3 between the respective blades 208-1u, 208-2u, and 208-3u of the pattern blades 208-1, 208-2, and 208-3 may range from about 100 μm to about 5000 μm in an X or Y direction, specifically, about 200 μm to about 3000 μm. Sizes d1, d2, d3, and d4 of the pattern blades 208-1, 208-2, and 208-3 may vary depending on the number of blades 208-1u, 208-2u, and 208-3u. Each of the sizes d1, d2, d3, and d4 of the pattern blades 208-1, 208-2, and 208-3 having at least two blades 208-1u, 208-2u, and 208-3u in a widthwise direction and/or a lengthwise direction may be about 120 μm or more.

As shown in FIGS. 14C-14H, each of the blades 208-1u, 208-2u, and 208-3u respectively constituting the pattern blades 208-1, 208-2, and 208-3 may have a triangular, square, or elliptical sectional shape. In addition, the pattern blades 208-1, 208-2, and 208-3 may have one of various sectional shapes. Portions under dashed lines of FIG. 14B may contact the support structure 130.

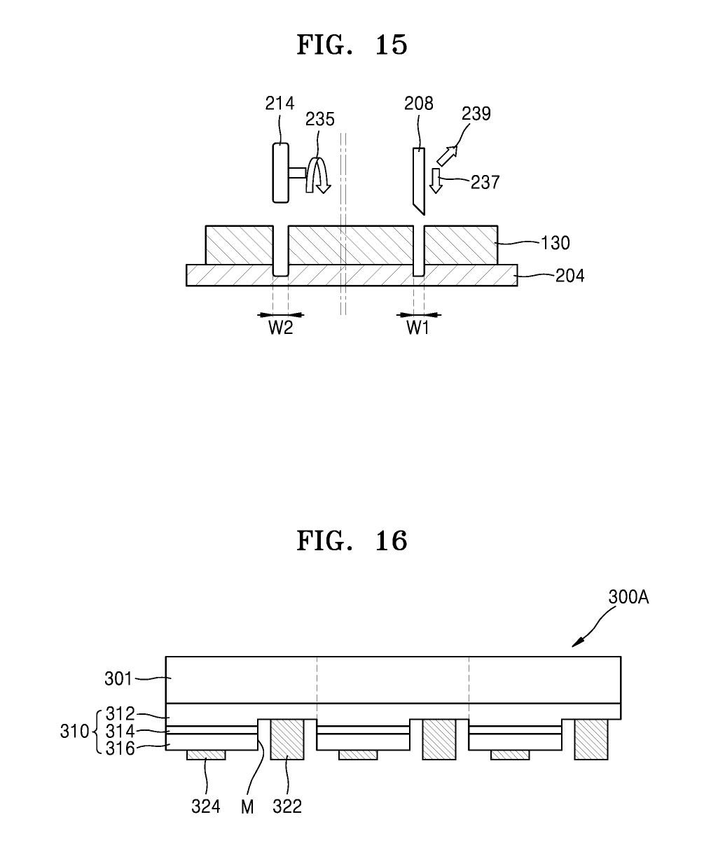

FIG. 15 is a cross-sectional view of a cutting method used for the above-described method of manufacturing an LED package, according to an example embodiment.

Specifically, a left diagram of FIG. 15 illustrates a case in which a support structure 130 disposed on an adhesive tape 204 is singulated by a sawing process using a sawing blade wheel 214. A right diagram of FIG. 15 illustrates a case in which the support structure 130 disposed on the adhesive tape 204 is singulated by a cutting process by using a pattern blade 208 instead of the sawing process.

When the support structure 130 is sawed by using the sawing blade wheel 214, rotary force 235 may be applied to the support structure 130. When the support structure 130 is cut by the pattern blade 208, vertical force 237 vertical to a top surface of the support structure 130 and horizontal force 239 parallel to the top surface of the support structure 130 may be applied to the support structure 130. When the sawing blade wheel 214 is used, oscillation may be applied to the support structure 130 along with the rotary force 235 so that a sawing width W2 may be, for example, 100 μm or more. When the pattern blade 208 is used, since only the vertical force 237 or the horizontal force 239 is applied to the support structure 130, a cutting width W1 may be less than the sawing width W2 and, for example, 100 μm or less, specifically, about 50 μm or less. In addition, when the pattern blade 208 is used, a cutting time may be at least about ¼ shorter than when the sawing blade wheel 214 is used.

FIGS. 16 to 19 are cross-sectional views of a method of manufacturing an LED package, according to an example embodiment of the inventive concept.

Specifically, FIGS. 16 to 19 illustrate a method of manufacturing an LED package, which is similar to the method of manufacturing the LED package shown in FIGS. 2A to 11, except that a semiconductor stack structure 310 has a mesa-etched structure M.

Referring to FIG. 16, initially, a wafer 301, on which the semiconductor stack structure 310 is formed, may be prepared. The semiconductor stack structure 310 may be an epitaxial layer formed on the wafer 301 to form a plurality of LED chips 300A. The semiconductor stack structure 310 may include a first semiconductor layer 312, an active layer 314, and a second semiconductor layer 316. Since the semiconductor stack structure 310 corresponds to the semiconductor stack structure 110 of FIG. 2, descriptions thereof are omitted.

First and second electrodes 322 and 324 may be provided in each individual LED region. The first and second electrodes 322 and 324 may be respectively connected to first and second semiconductor layers 312 and 316. Since the first and second electrodes 322 and 344 respectively correspond to the first and second electrodes 122 and 124 of FIG. 2, descriptions thereof are omitted. Partial regions of the first semiconductor layer 312, the second semiconductor layer 316, and the active layer 314 are mesa-etched, and the first electrode 322 may be formed in a mesa-etched structure M.

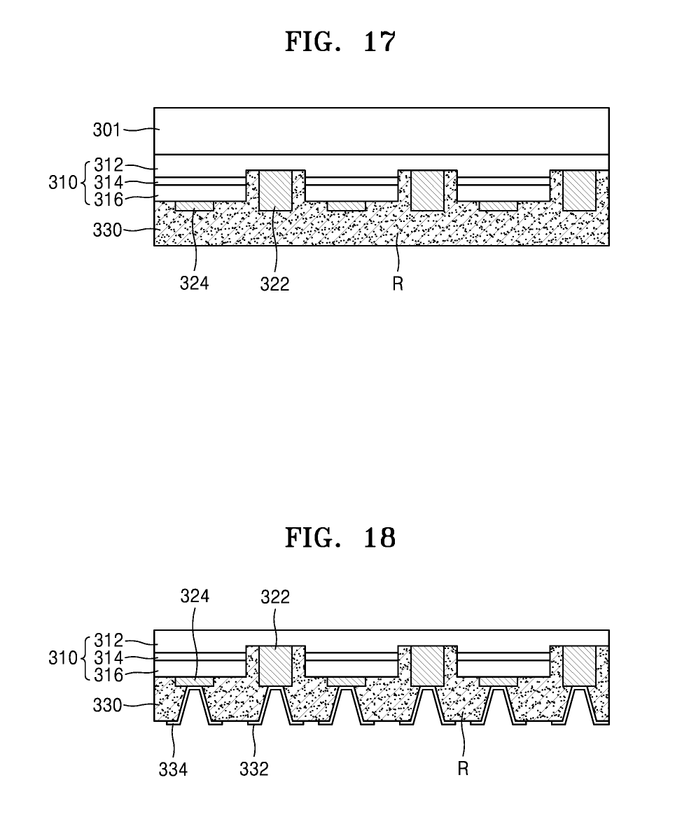

Referring to FIG. 17, a support structure 330 may be formed on a surface of the semiconductor stack structure 310 on which the first and second electrodes 322 and 324 are disposed. The support structure 330 may be a support substrate. The support structure 330 may include a resin containing high-reflective powder R. The support structure 330 may be a curing resin or a semi-curing resin. Since the support structure 330 may correspond to the support structure 130 of FIG. 3, descriptions thereof are omitted.

The support structure 330 may be highly flexible because the support structure 330 uses a resin structure that is semi-cured or remains flowable before cured. Thus, the support structure 330 may be effectively adhered to the surface of the semiconductor stack structure 310 on which the first and second electrodes 322 and 324 are formed. In particular, since the support structure 330 is formed by using a curing resin or a semi-curing resin on a mesa-etched non-planar surface (i.e., a stepped surface) as in the present embodiment, the semiconductor stack structure 310 may be bonded to the support structure 330 over a sufficient area covering the mesa-etched structure area.

Referring to FIG. 18, a process of forming connection electrodes 332 and 334 to be connected to an external circuit may be performed on the support structure 330. Through holes H may be formed in the support structure 330 until the first and second electrodes 322 and 324 are exposed. First and second connection electrodes 332 and 334 may be formed in the support structure 330 to be respectively connected to portions of the first and second electrodes 322 and 324 exposed by the through holes H. Since the first and second connection electrodes 332 and 334 respectively correspond to the first and second connection electrodes 132 and 134 of FIG. 5, descriptions thereof are omitted. Subsequently, the wafer 301 serving as a growth substrate may be separated from the semiconductor stack structure 310.

As described above with reference to FIGS. 3 to 5, the electrode forming process and the substrate removing process may be performed in a changed order. For example, after the first and second electrodes 322 and 324 and/or bumper extension electrodes (or connection electrodes) are previously formed to a thickness equal to that of the support structure 330, a resin support structure of silicon, epoxy, or polymer may be formed, and the bumper extension electrodes may be exposed by using a grinding process, a cutting process, or an etching process. Also, a process of removing the wafer 301 serving as the growth substrate may be omitted. In this case, subsequent processes may be performed on the surface of the wafer 301.

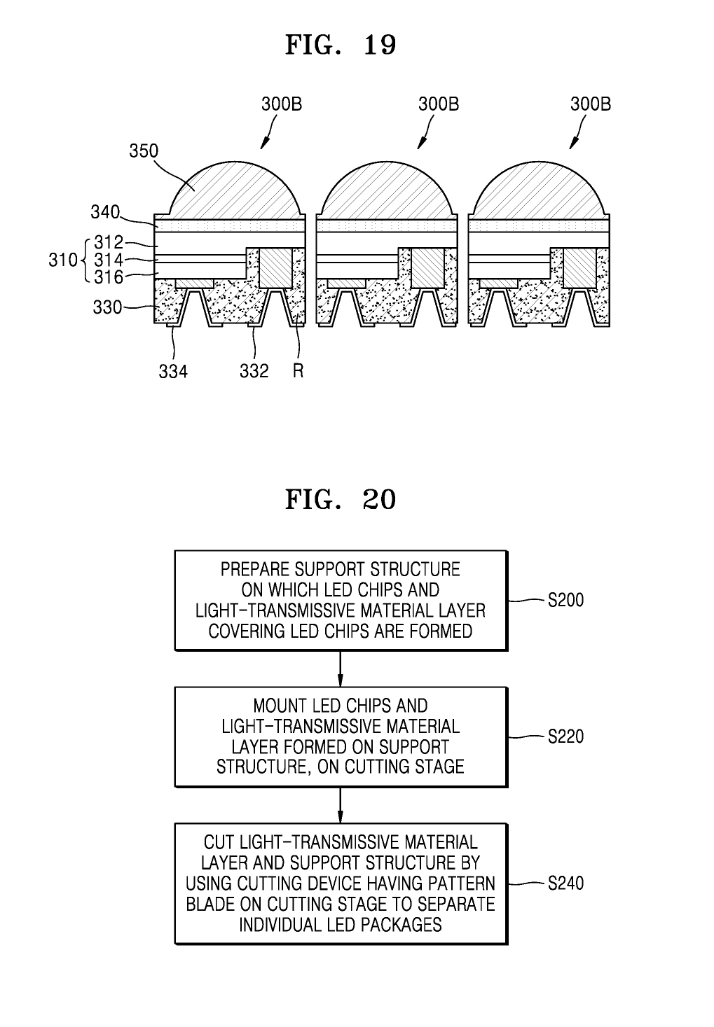

Referring to FIG. 19, a wavelength conversion layer 340 serving as a light-transmissive material layer and a lens layer 350 may be formed on a surface of the semiconductor stack structure 310 from which the wafer 301 is removed. Since the wavelength conversion layer 340 and the lens layer 350 respectively correspond to the wavelength conversion layer 140 and the lens layer 150 of FIG. 9, descriptions thereof are omitted.

Subsequently, as shown in FIGS. 13A to 13C, the LED chips 300A (including the semiconductor stack structure 100), the lens layer 350 and the wavelength conversion layer 340 formed on the support structure 330 may be mounted on a cutting stage 202. As described above, the wavelength conversion layer 140 and the lens layer 150 may constitute a light-transmissive material layer. The lens layer 350, the wavelength conversion layer 340, the semiconductor stack structure 310, and the support structure 330 may be singulated (or separated) along boundaries distinguishing a plurality of LED chips 100A from one another by using a cutting process on the cutting stage (refer 202 in FIGS. 13A to 13C), thereby forming individual LED packages 300B. Since the singulation process is described above, descriptions thereof are omitted.

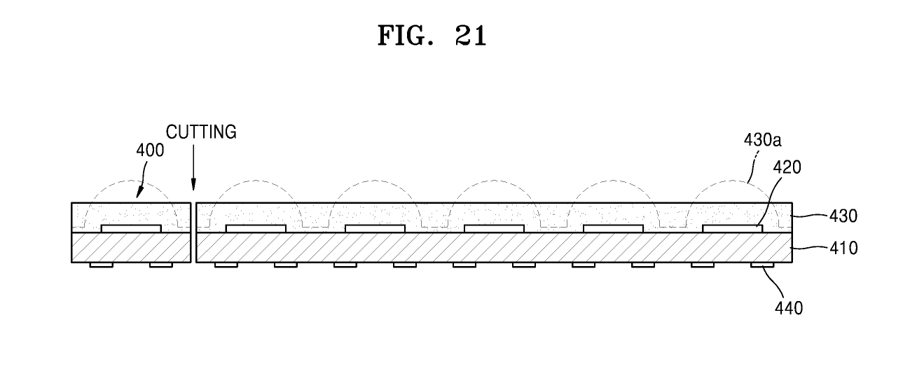

FIG. 20 is a flowchart of a method of manufacturing an LED package, according to an example embodiment, and FIGS. 21 to 23 are diagrams of a method of manufacturing an LED package, according to an example embodiment.

Specifically, the method of manufacturing the LED package may start from a process of preparing a support structure 410 on which LED chips 420 and a light-transmissive material layer 430 or 430a covering the LED chips 420 are formed (step S200). Since the support structure 410 may correspond to the support structure 130 of FIG. 3, descriptions thereof are omitted. That is, the method of manufacturing an LED package may include preparing a plurality of LED chips 420, mounting the plurality of LED chips 420 on the support structure 410, and forming a light-transmissive material layer 430 on the support structure 410 to cover the LED chips 420.

The support structure 410 may be a resin substrate. The support structure 410 may include a silicone resin, an epoxy resin, or a mixture thereof. A circuit pattern 440 may be formed under the support structure 410. The light-transmissive material layer 430 may be a planarized material layer. A light-transmissive material layer 430a may have a lens shape illustrated with a dashed line of FIG. 21.

The LED chip 420 may emit blue light, green light, or red light according to a material of a compound semiconductor constituting the LED chip 420. For example, a blue LED chip may have an active layer including a plurality of quantum well layers formed by alternately forming a GaN layer and an InGaN layer. A P-type clad layer and an N-type clad layer may be respectively formed of a compound semiconductor (i.e., Al_{X}Ga_{Y}N_{Z}) on and under the active layer.

The LED chips 420 and the light-transmissive material layer 430 or 430a formed on the support structure 410 may be mounted on the cutting stage (refer to 202 in FIGS. 13A to 13C) (step S220). Since a mounted structure is described above, descriptions thereof are omitted.

The light-transmissive material layer 430 or 430a and the support structure 410 may be cut on the cutting stage (refer to 202 in FIGS. 13A to 13C) by using the cutting device 200 having the pattern blade 208, thereby singulating (or separating) individual LED packages 400 (step S240).

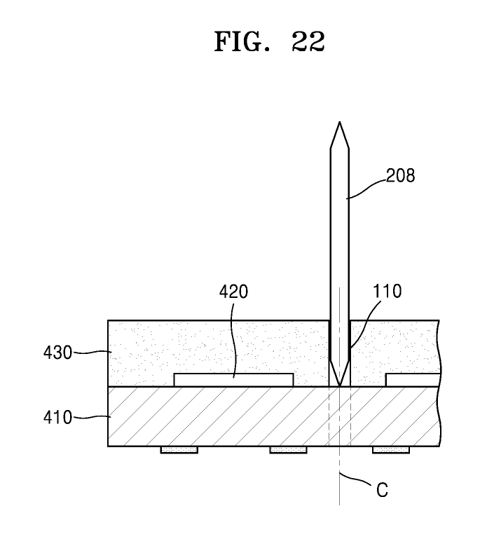

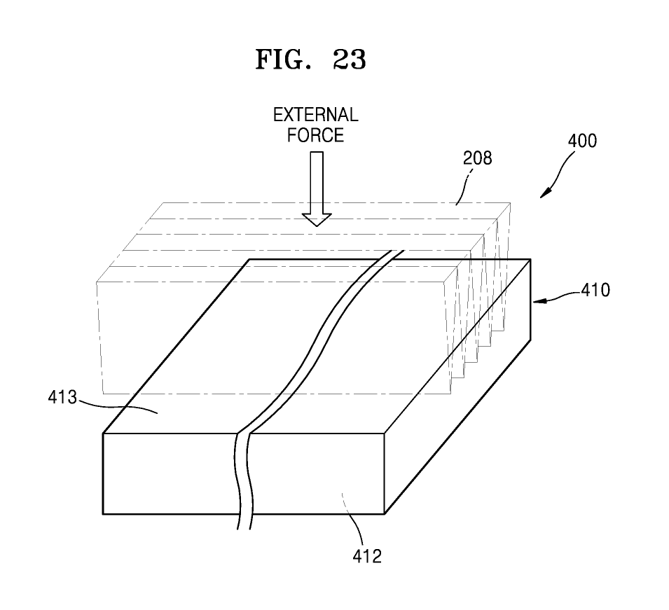

Although the singulation (or separation) process is described above, this process will now be described again with reference to FIGS. 22 and 23. FIGS. 22 and 23 are respectively a cross-sectional view and a perspective view for explaining the singulation process. When the LED package 400 is manufactured, as shown in FIGS. 22 and 23, the light-transmissive material layer 430 and the support structure 410 may be cut between a plurality of LED chips 420 by applying external force to the pattern blade 208 downward from above. In FIG. 22, reference numeral C denotes a central line of force applied to the pattern blade 208. The light-transmissive material layer 430 is not illustrated in FIG. 23 for brevity of description. In FIG. 23, the support structure 410 may have a rear surface 412 and a surface 413.

As described above, the cutting process may be performed by using the cutting device 200 having the pattern blade 208. To obtain a high cutting speed, the light-transmissive material layer 430 and the support structure 410 may be cut at one time by using a mechanical cutting method.

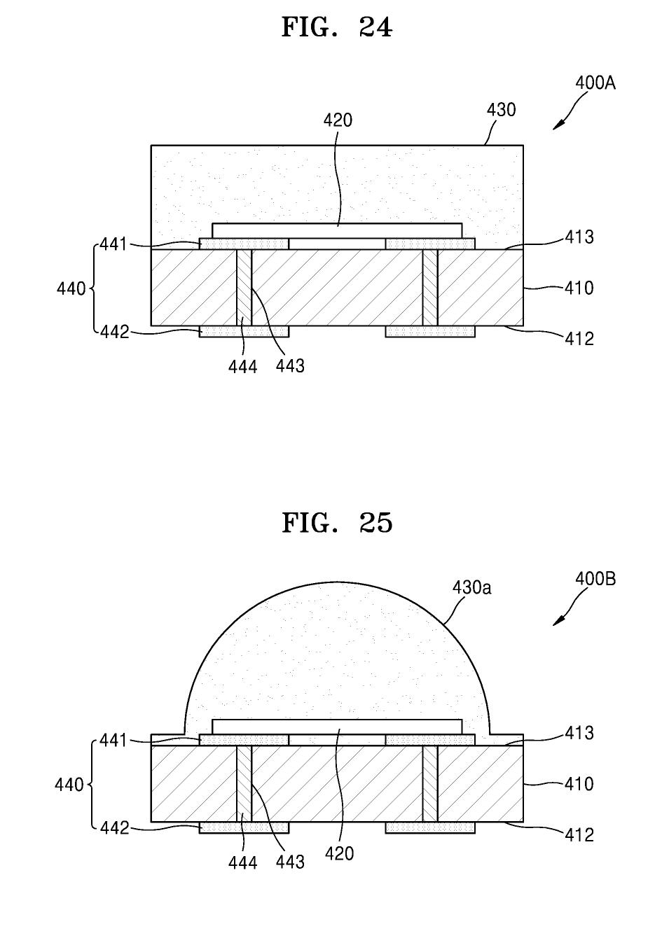

FIGS. 24 to 26 are cross-sectional views having various structures, which may be manufactured by using the method of manufacturing the LED package shown in FIGS. 21 to 23.

Specifically, each of LED packages 400A, 400B, and 400C may include a support structure 410, an LED chip 420, and a light-transmissive material layer 430 or 430a. A circuit pattern 440 may be formed on the support structure 410. First and second circuit patterns 441 and 442 may be formed on a top surface 413 and a bottom surface 412 of the support structure 410. The first and second circuit patterns 441 and 442 may be connected to each other by via holes 443 formed through the support structure 410. For example, the via holes 443 may be filled with a conductive material 444 so that the first and second circuit patterns 441 and 442 may be electrically connected to each other. The first and second circuit patterns 441 and 442 may be formed by forming a conductive material layer on the top surface 413 and the bottom surface 412 by using a printing process or an electroplating process. The first circuit pattern 441 may include two patterns corresponding respectively to an anode electrode (not shown) and a cathode electrode (not shown) of the LED chip 420.

The light-transmissive material layer 430 may cover the LED chip 420 and function to protect the LED chip 420. Furthermore, the light-transmissive material layer 430 may function to control directionality of light radiated from the LED chip 420 and control color of light radiated from the LED chip 420. The light-transmissive material layer 430 may be formed a light-transmissive material (e.g., light-transmissive silicon) that may transmit light radiated from the LED chip 420). Although FIG. 24 illustrates a planar light-transmissive material layer 430, the inventive concept is not limited thereto. The light-transmissive material layer 430 may have one of various unshown shapes.

When the light-transmissive material layer 430 functions to control the directionality of light, the light-transmissive material layer 430a may be a lens layer as shown in FIG. 25. The lens layer may have one of various shapes, such as a concave lens shape and a convex lens shape.

The light-transmissive material layer 430 or 430a may be a phosphor layer configured to control color of light. The phosphor layer may be appropriately selected according to desired color. Phosphor forming the phosphor layer may be distributed in a light-transmissive material forming the light-transmissive material layer 430 or 430a. Although a case in which the light-transmissive material layer 430 or 430a is a single layer has been described, the inventive concept is not limited thereto. For example, the light-transmissive material layer 430 or 430a may have a multi-layered structure including at least three layers.

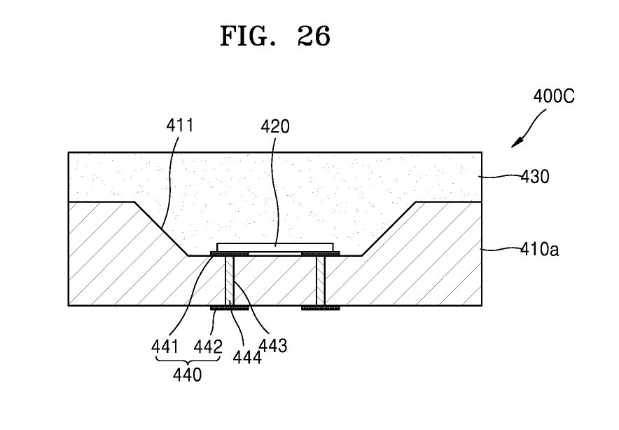

FIGS. 24 to 26 illustrates structures in which the LED chip 420 is directly electrically connected to the first circuit pattern 441 formed on the surface 413 of the support structure 410, but the inventive concept is not limited thereto. For example, the LED chip 420 may be connected to the first circuit pattern 441 by conductive wires (not shown). As shown in FIG. 26, a recess unit 411 may be formed in the surface of the support structure 410a. The LED chip 420 may be mounted on a bottom surface of the recess unit 411. Side surfaces of the recess unit 411 may be inclined upward so that light radiated from the LED chip 420 faces outward to increase optical efficiency. The side surfaces of the recess unit 411 may be reflection surfaces.

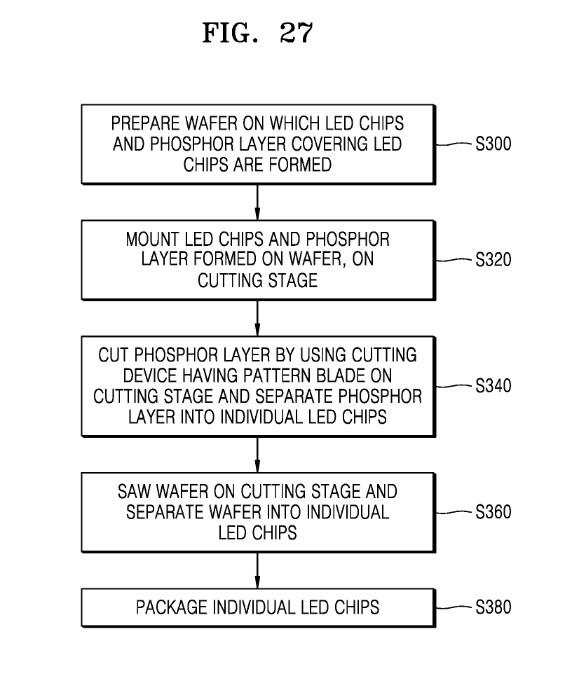

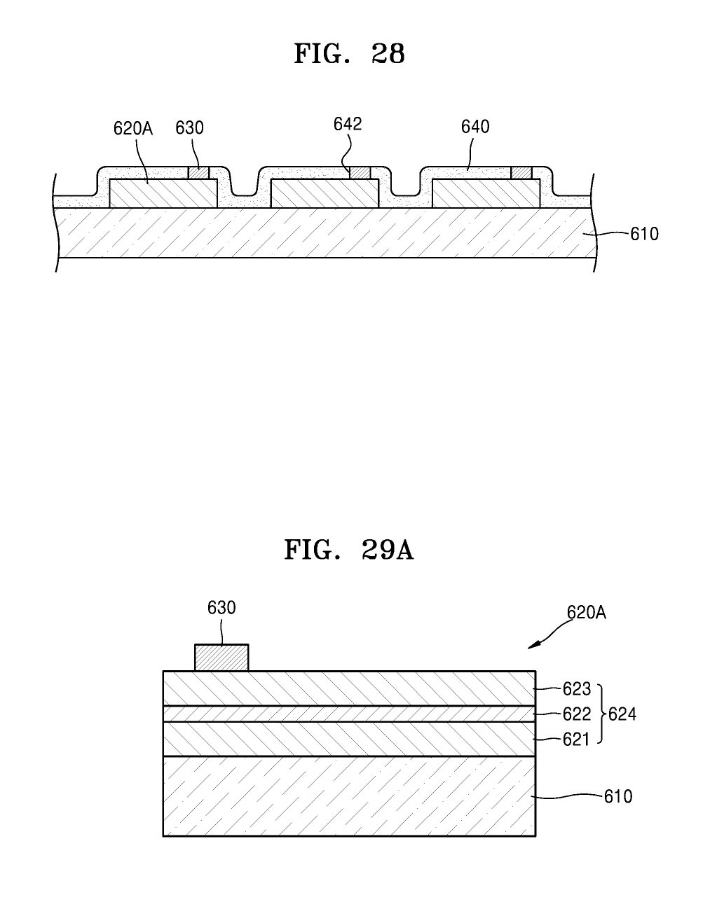

FIG. 27 is a flowchart of a method of manufacturing an LED package, according to an example embodiment, and FIGS. 28 to 31 are diagrams of a method of manufacturing an LED package, according to an example embodiment.

Specifically, the method of manufacturing the LED package may start from a process of preparing a wafer 610 on which LED chips 620A including electrodes 630 and a phosphor layer 640 covering the LED chips 620A are formed (step S300). That is, the method of manufacturing the LED package may include forming a plurality of LED chips 620A on the wafer 610 and forming a phosphor layer 640 to cover the LED chips 620A.

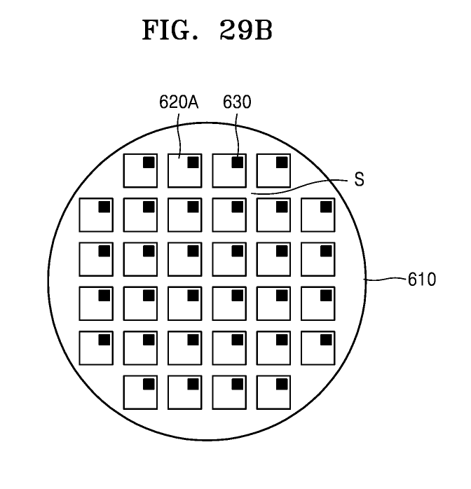

The LED chip 620A according to an example embodiment will be schematically described with reference to FIGS. 29A and 29B. The LED chip 620A may include a semiconductor stack structure 624 stacked on the wafer 610 (e.g., a silicon (Si) wafer).

The semiconductor stack structure 624 may include a first semiconductor layer 621, an active layer 622, and a second semiconductor layer 623, which may be sequentially stacked on the wafer 610. The first semiconductor layer 621 and the second semiconductor layer 623 may be formed of an n-type semiconductor layer and a p-type semiconductor layer, respectively. Each of the first semiconductor layer 621 and the second semiconductor layer 623 may be formed of a nitride layer, for example, AlₓIn_{y}Ga_{1-x-y}N (0≦x≦1, 0≦y≦1, and 0≦x+y≦1). The active layer 622 may include a plurality of quantum well layers by alternately forming a GaN layer and an InGaN layer. Since the semiconductor stack structure 624 may correspond to the semiconductor stack structure 110 of FIG. 1, descriptions thereof are omitted.

A second electrode 630 may be formed on the semiconductor stack structure 624. The second electrode 630 may be a p-type electrode. The wafer 610 may function as an n-type electrode. Although FIGS. 29A and 29B illustrate a case in which the LED chip 620A has a vertical electrode structure, the inventive concept is not limited thereto, and the LED chip 620A may have, for example, a horizontal electrode structure. As described below, a plurality of LED chips 620A formed on the wafer 610 may be singulated by performing a cutting process along a cutting line S.

The phosphor layer 640 may be a phosphor film. The phosphor film may be a film in which phosphor particles are distributed in a silicone resin or an epoxy resin. To form an LED configured to emit white light, the LED chip 620A may be an LED chip configured to emit blue light, and the phosphor particles may be particles of yellow phosphor or particles of a mixture of green phosphor and red phosphor. The phosphor film may have a thickness of about 10 μm to about 100 μm. A plurality of holes 642, each of which corresponds to the second electrode 630, may be formed in the phosphor film. Each of the holes 642 may be formed by using a puncher. The phosphor layer 640 may be formed by adhering the phosphor film onto the wafer 610. In this case, the phosphor film may be adhered onto the wafer 610 such that each of the holes 642 corresponds to the second electrode 630 to expose the second electrode 630.

The LED chips 620A and the phosphor layer 640 formed on the wafer 610 may be mounted on the cutting stage (refer to 202 in FIGS. 13A to 13C) (step S320). Although FIGS. 13A to 13C illustrate a case in which a substrate, for example, a support structure 130 including a resin structure, is mounted, the present embodiment is a case in which the wafer 610 is mounted as the support structure 130. An adhesive tape 204 of the wafer 610 may be adhered during the mounting of the wafer 610 on the cutting stage 202. Since the process of mounting the wafer 610 is the same as the process of mounting the support structure 130, descriptions thereof are omitted.

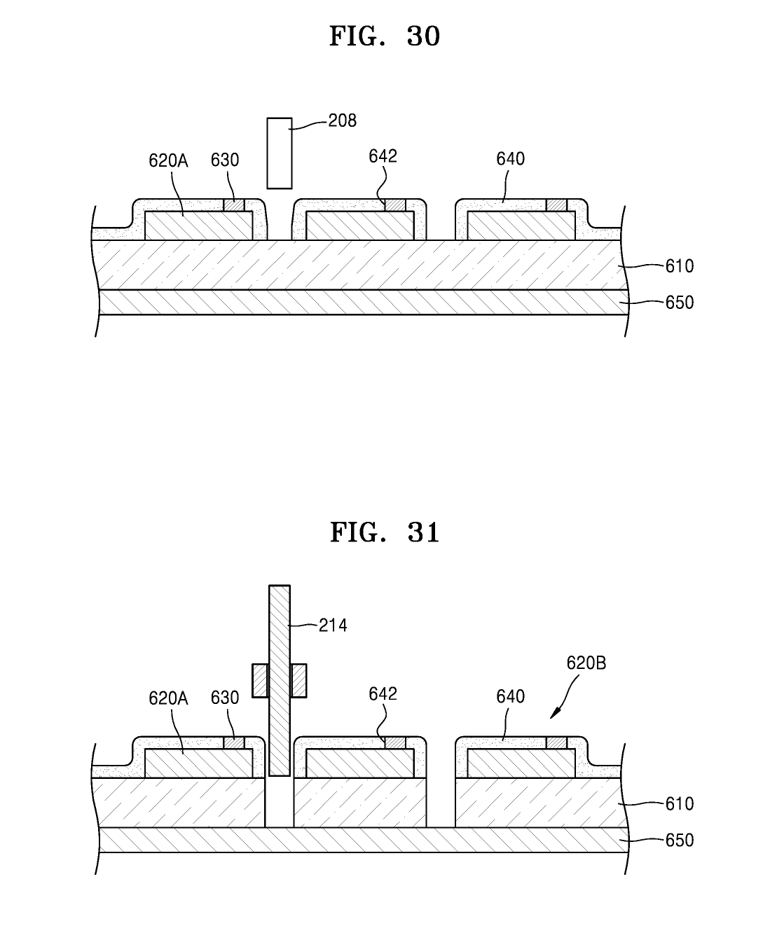

As described with reference to FIG. 30, the phosphor layer 640 between a plurality of LED chips 620A may be cut and separated into respective LED chips 620A by using a cutting device 200 having a pattern 208 on the cutting stage (refer to 202 in FIGS. 13A to 13C) (step S340). When the phosphor layer 640 is separated by using the cutting device 200 having the pattern blade 208 into the LED chips 620A, discoloration of the phosphor layer 640 may be prevented by reducing burning of the phosphor layer 640.

As described above, the cutting device 200 may include a driver apparatus 210 connected to the pattern blade 208 and configured to drive the pattern blade 208. The phosphor layer 640 may be cut while moving the pattern blade 208 by using the driver apparatus 210 on the wafer 610 in widthwise and lengthwise direction.

As shown in FIG. 31, the wafer 610 between a plurality of LED chips 620A may be sawed by using a sawing blade wheel 214 on the cutting stage (refer to 202 in FIGS. 13A to 13C), thereby singulating (or separating) individual LED chips 620B (step S360) from one another. After the phosphor layer 640 is separated to singulate the LED chips 620A, the wafer 610 may be rapidly sawed by using the sawing blade wheel 214, so that a sawing time may reduce to improve productivity.

Next, after the individual LED chips 620B are singulated, a process of packaging each of the LED chips 620B may be performed (step S380). For example, each of the LED chips 620B may be mounted on an interconnection substrate (not shown) and electrically connected to the interconnection substrate.

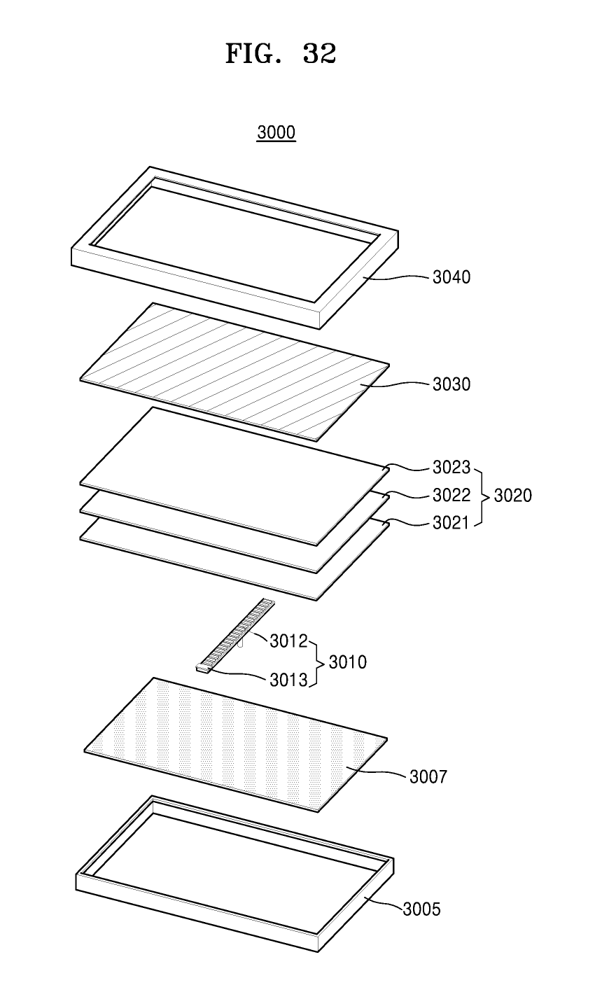

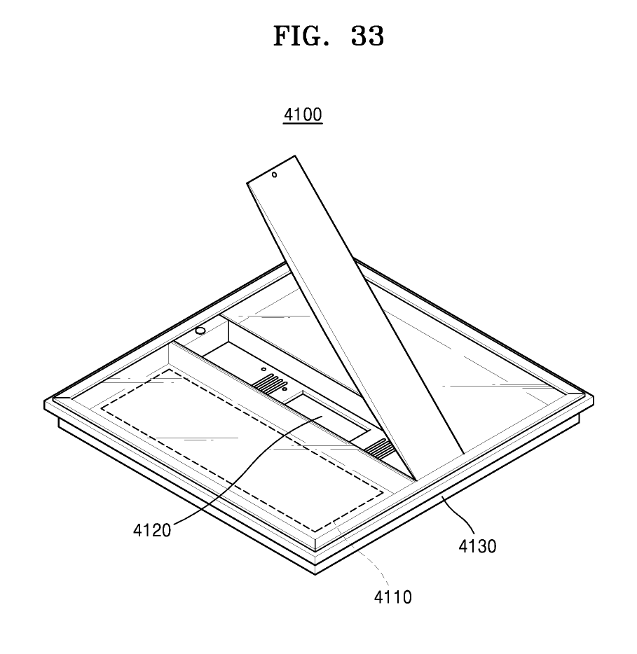

FIG. 32 is an exploded perspective view of an example of a backlight (BL) assembly including an LED package manufactured, according to an example embodiment.

Specifically, a direct-light-type BL assembly 3000 may include a lower cover 3005, a reflection sheet 3007, a light-emitting module 3010, an optical sheet 3020, an LC panel 3030, and an upper cover 3040. According to an example embodiment, the LED package may be used as a light-emitting module 3010 included in the direct-light-type BL assembly 3000.

According to an example embodiment, the light-emitting module 3010 may include at least one LED package, an LED array 3012 including a circuit substrate, and a communication module 3013. A home-network communication may be embodied by using the communication module 3013. For example, the communication module 3013 may be a wireless communication module using Zigbee, WiFi, or LiFi, and control illumination systems installed inside or outside a house (e.g., turn on and off an illumination system or control a brightness of the illumination system) by using a smartphone or a wireless controller. Furthermore, electronic products and automobile systems (e.g., TV, a refrigerator, an air conditioner, a door lock, and automobiles) used inside or outside the house may be controlled by using a LiFi communication module using visible wavelengths of the illumination systems installed inside or outside the house.

The LED array 3012 may receive power required for emitting light from an LED driver disposed outside the direct-light-type BL assembly 3000. The LED driver may sense rank information regarding the LED array 3012, which is stored in the communication module 3013, and control current supplied to the LED array 3012 based on the sensed rank information.

The optical sheet 3020 may be disposed on the light-emitting module 3010 and includes a diffuser sheet 3021, a condensing sheet 3022, and a protection sheet 3023. That is, the diffuser sheet 3021 may diffuse light emitted by the light-emitting module 3010, and the condensing sheet 3022 may condense the light diffused by the diffuser sheet 3021 to increase luminance. The protection sheet 3023 may protect the condensing sheet 3022 and ensure a viewing angle. The diffuser sheet 3021, the condensing sheet 3022, and the protection sheet 3023 may be sequentially prepared on the light-emitting module 3010. The upper cover 3040 may surround an edge of the optical sheet 3020 and be assembled with the lower cover 3005.

The LC panel 3030 may be further provided between the optical sheet 3020 and the upper cover 3040. The LC panel 3030 may include a pair of substrates, for example, a first substrate (not shown) and a second substrate (not shown), which may be bonded to each other with an LC layer therebetween. A plurality of gate lines may intersect a plurality of data lines on the first substrate to define pixel regions. Thin-film transistors (TFTs) may be provided at intersections of the pixel regions, and connected to pixel electrodes mounted in the respective pixel regions to correspond one-to-one to the pixel electrodes. The second substrate may include red (R), green (G), and blue (B) color filters respectively corresponding to the pixel regions and a black matrix covering edges of the respective color filters, the gate lines, the data lines, and the TFTs.

FIG. 33 is a schematic diagram of a flat-panel illumination system 4100 including an LED array unit (or a light-emitting module) in which an LED package manufactured as described above is arranged, according to an example embodiment.

Specifically, the flat-panel illumination system 4100 may include a light source 4110, a power supply device 4120, and a housing 4130. The light source 4110 may include an LED array unit (or a light-emitting module) including an LED package according to an example embodiment. The power supply device 4120 may include an LED driver.

The light source 4110 may have a generally planar shape. According to an example embodiment, the LED array unit may include an LED array and a communication module unit configured to store rank information of the LED array.

The power supply device 4120 may be configured to supply power to the light source 4110. According to an example embodiment, the power supply device 4120 may include a variable current output unit and a communication module unit.

The housing 4130 may form a space to contain the light source 4110 and the power supply device 4120 and have a hexahedral shape having one open side surface, but the inventive concept is not limited thereto. The light source 4110 may be disposed to emit light through the open side surface of the housing 4130.

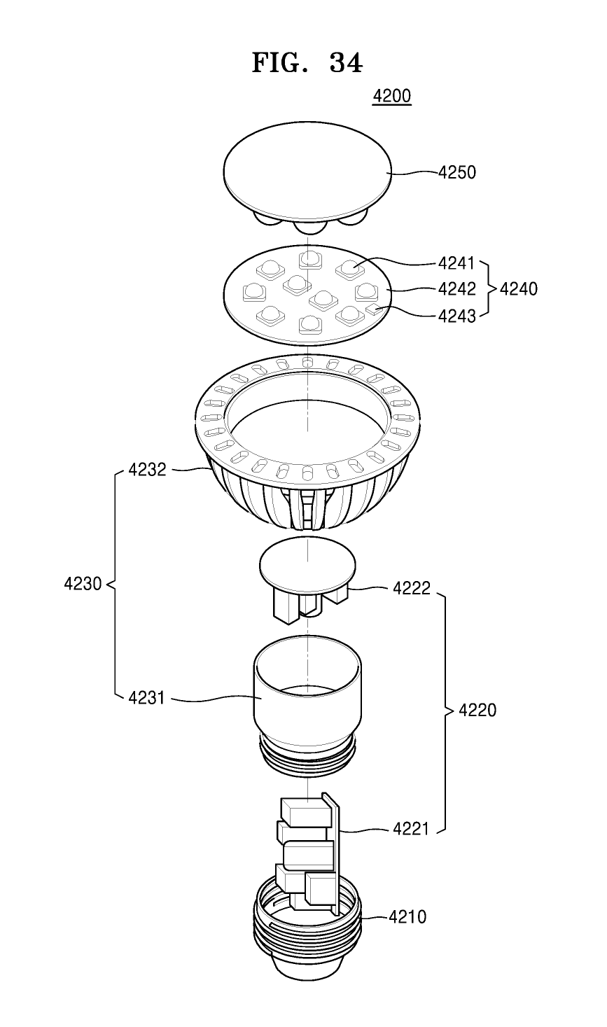

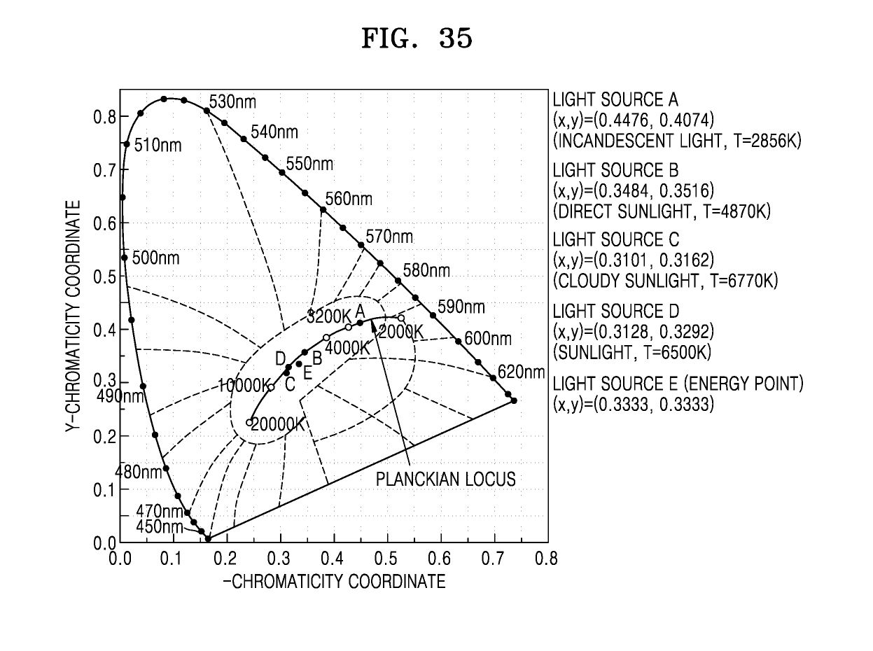

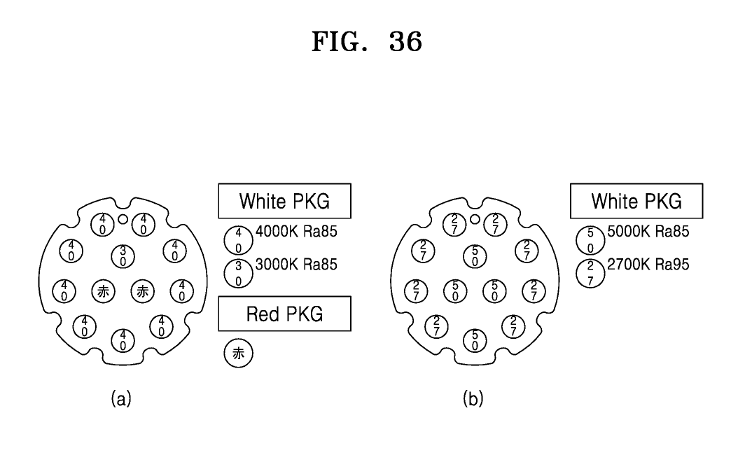

FIG. 34 is a schematic diagram of a bulb-type lamp, which is an illumination system 4200 including an LED array unit (or a light-emitting module) in which an LED package manufactured as described above is arranged, according to an example embodiment, and FIG. 35 is an international commission on illumination (CIE) chromaticity diagram of a complete radiator spectrum, which is applicable to an LED package manufactured as described above is arranged, according to an example embodiment.

Specifically, the illumination system 4200 may include a socket 4210, a power supply unit 4220, a heat radiation unit 4230, a light source 4240, and an optical unit 4250. The light source 4240 may include an LED array unit, and the power supply unit 4220 may include the above-described LED driver.

The socket 4210 may be configured to be capable of being replaced by an illumination system of the related art. Power supplied to the illumination system 4200 may be applied through the socket 4210. As shown in FIG. 34, the power supply unit 4220 may be formed by assembling a first power supply unit 4221 and a second power supply unit 4222. The power supply unit 4220 may include the LED driver as described above. That is, the power supply unit 4220 may include a variable current output unit.

The heat radiation unit 4230 may include an internal heat radiation unit 4231 and an external heat radiation unit 4232. The internal heat radiation unit 4131 may be directly connected to the light source 4240 and/or the power source unit 4220 so that heat may be transmitted to the external heat radiation unit 4232. The optical unit 4250 may include an internal optical unit (not shown) and an external optical unit (not shown) and may be configured to uniformly disperse light emitted by the light source 4240.

The light source 4240 may receive power from the power source unit 4220 and emit light to the optical unit 4250. The light source 4240 may include an LED array unit, according to one of the above example embodiments. The light source 4240 may include at least one LED package 4241 according to one of the above example embodiments, a circuit substrate 4242, and a communication module 4243. The communication module 4243 may store rank information and communication information of the LED packages 4241.

A plurality of LED packages 4241 included in the light source 4240 may be of the same kind to generate light having the same wavelength. Alternatively, the plurality of LED packages 4241 included in the light source 4240 may be of different kinds to generate light having different wavelengths. For example, the LED packages 4241 may include a blue LED, a white LED manufactured by combining yellow, green, red, or orange phosphors, and at least one of violet, blue, green, red, or infrared (IR) LEDs so as to control a color temperature of white light and a color rendering index (CRI). Alternatively, when an LED chip emits blue light, an LED package including at least one of yellow, green, and red phosphors may be configured to emit white light having various color temperatures according to a combination ratio of the phosphors. Alternatively, an LED package in which a green or red phosphor is applied to the blue LED chip may be configured to emit green or red light. The LED package configured to emit white light may be combined with the LED package configured to emit green or red light so as to control a color temperature of white light and CRI. Also, the LED package 4241 may include at least one of LEDs configured to emit violet, blue, green, red, or IR light.

In this case, the illumination system 4200 may control CRI in sodium (Na) to the level of sunlight, and generate various white light beams at a color temperature of about 1500K to about 20000K. When necessary, the illumination system 4200 may generate violet, blue, green, red, or orange visible light or IR light and control color of illumination according to an ambient atmosphere or mood. Also, the illumination system 4200 may generate light having a specific wavelength to facilitate growth of plants.

White light generated by a combination of the blue LED with yellow, green, red phosphor and/or green and red LEDs may have at least two peak wavelengths. As shown in FIG. 35, coordinates (x, y) of the white light in a CIE 1931 coordinate system may be located on a segment connecting (0.4476, 0.4074), (0.3484, 0.3516), (0.3101, 0.3162), (0.3128, 0.3292), and (0.3333, 0.3333) or located in a region surrounded with the segment and a blackbody radiator spectrum. A color temperature of the white light may be between 1500K and 20000K.

FIG. 36 is a diagram of an example of an LED package manufactured by using a method of manufacturing an LED package as described above is arranged, according to an example embodiment. The LED package according to the present embodiment may correspond to the light source 4240 of FIG. 34.

Specifically, for example, a white LED module of which a color temperature may be controlled within a range of about 2000K to about 4000K and CRI (Ra) is about 85 to about 99 may be manufactured by combining a white LED package having a color temperature of about 4000K and a red LED package having a color temperature of about 3000K.

In other example embodiments, a white light-emitting package module of which a color temperature may be controlled within a range of about 2700K to about 5000K and CRI (Ra) is about 85 to about 99 may be manufactured by combining a white LED package having a color temperature of about 2700K and a white LED package having a color temperature of about 5000K. The number of LED packages having respective color temperatures may mainly depend on a default color temperature. In an illumination system of which a default color temperature is about 4000K, the number of LED packages having a color temperature of about 4000K may be set to be larger than the number of LED packages having a color temperature of about 3000K or the number of red LED packages.

Phosphors may have formulas and colors as follows.

Oxide-based phosphors: yellow and green Y₃Al₅O₁₂:Ce, Tb₃Al₅O₁₂:Ce, Lu₃Al₅O₁₂:Ce

Silicate-based phosphors: yellow and green (Ba,Sr)₂SiO₄:Eu, yellow and orange (Ba,Sr)₃SiO₅:Ce

Nitride-based phosphors: green β-SiAlON:Eu, yellow La₃Si₆N₁₁:Ce, orange α-SiAlON:Eu, red CaAlSiN₃:Eu, Sr₂Si₅N₈:Eu, SrSiAl₄N₇:Eu, SrLiAl₃N₄:Eu, Ln₄₋ₓ(Eu_{z}M_{1-z})ₓSi_{12-y}Al_{y}O_{3+x+y}Ni_{18-x-y} (0.5≦x≦3, 0≦z≦0.3, 0≦y≦4)—Formula (1)

In Formula (1), Ln may be at least one element selected from the group consisting of a Group Ma element and a rare-earth element, and M may be at least one element selected from the group consisting of calcium (Ca), barium (Ba), strontium (Sr), and magnesium (Mg).

Fluoride-based phosphors: KSF-based red K₂SiF₆:Mn₄+, K₂TiF₆:Mn₄+, NaYF₄:Mn₄+, NaGdF₄:Mn₄+

Compositions of the phosphors should be based on stoichiometry, and respective elements may be replaced by other elements in respective groups in the periodic table. For example, Sr may be replaced by Group II elements (alkaline earths), such as Ba, Ca, or Mg, and Y may be replaced by a lanthanum-based element, such as Tb, Lu, Sc, or Gd. Also, europium (Eu) serving as an activator may be replaced by cerium (Ce), terbium (Tb), praseodymium (Pr), erbium (Er), or ytterbium (Yb) according to a desired energy level. An activator may be used alone or a co-activator may be further applied to vary characteristics. Furthermore, materials, such as QDs, may be used as materials capable of replacing phosphors, and phosphors and QDs may be used alone or in combination with one another.

A QD may have a structure including a core (about 3 nm to about 10 nm), such as CdSe or InP, a shell (about 0.5 nm to about 2 nm), such as ZnS and ZeSe, and a ligand for stabilizing the core and the shell, and may be embodied in various colors according to size.

Although the present example embodiment describes a case in which a wavelength conversion material is contained in an encapsulant, the wavelength conversion material may be bonded as a film type on a top surface of an LED chip or coated to a uniform thickness on the top surface of the LED chip.

The following Table 1 shows types of phosphors in respective fields to which a white an LED using a blue LED chip (about 440 nm to about 460 nm) is applied.

TABLE 1

| Purpose | Phosphor |
|---|---|
| LED TV BLU | β-SiAlON: Eu2+ |
| | (Ca, Sr)AlSiN₃: Eu2+ |
| | La₃Si₆N₁₁: Ce3+ |
| | K₂SiF₆: Mn4+ |
| | SrLiAl3N4: Eu |
| | Ln₄₋ₓ(Eu₂M_{1-z})ₓSi_{12-y}Al_{y}O_{3+x+y}N_{18-x-y} |
| | (0.5 ≦ x ≦ 3, 0 < z < 0.3, 0 < y ≦ 4) |
| | K2TiF6: Mn4+ |
| | NaYF4: Mn4+ |
| | NaGdF4: Mn4+ |
| Illumination | Lu₃Al₃O₁₂: Ce3+ |
| | Ca-α-SiAlON: Eu2+ |
| | La₃Si₆N₁₁: Ce3+ |
| | (Ca, Sr)AlSiN₃: Eu2+ |
| | Y₃Al₅O₁₂: Ce3+ |
| | K₂SiF₆: Mn4+ |
| | SrLiAl3N4: Eu |
| | Ln₄₋ₓ(Eu₂M_{1-z})ₓSi_{12-y}Al_{y}O_{3-x-y}N_{18-x-y} |
| | (0.5 ≦ x ≦ 3, 0 < z < 0.3, 0 < y ≦ 4) |
| | K2TiF6: Mn4+ |
| | NaYF4: Mn4+ |
| | NaGdF4: Mn4+ |
| Side View | Lu₃Al₅O₁₂: Ce3+ |
| (Mobile, Note PC) | Ca-α-SiAlON: Eu2+ |
| | La₃Si₆N₁₁: Ce3+ |
| | (Ca, Sr)AlSiN₃: Eu2+ |
| | Y₃Al₅O₁₂: Ce3+ |
| | (Sr, Ba, Ca, Mg)2SiO4: Eu2+ |
| | K₂SiF₆: Mn4+ |
| | SrLiAl3N4: Eu |
| | Ln₄₋ₓ(Eu₂M_{1-z})ₓSi_{12-y}Al_{y}O_{3+x+y}N_{18-x-y} |
| | (0.5 ≦ x ≦ 3, 0 < z < 0.3, 0 < y ≦ 4) |
| | K2TiF6: Mn4+ |
| | NaYF4: Mn4+ |
| | NaGdF4: Mn4+ |
| Interior | Lu₃Al₅O₁₂: Ce3+ |
| (Head Lamp, etc.) | Ca-α-SiAlON: Eu2+ |
| | La₃Si₆N₁₁: Ce3+ |
| | (Ca, Sr)AlSiN₃: Eu2+ |
| | Y₃Al₅O₁₂: Ce3+ |
| | K₂SiF₆: Mn4+ |
| | SrLiAl3N4: Eu |
| | Ln₄₋ₓ(Eu2M_{1-z})ₓSi_{12-y}Al_{y}O_{3+x+y}N_{18-x-y} |
| | (0.5 ≦ x ≦ 3, 0 < z < 0.3, 0 < y ≦ 4) |
| | K2TiF6: Mn4+ |
| | NaYF4: Mn4+ |
| | NaGdF4: Mn4+ |

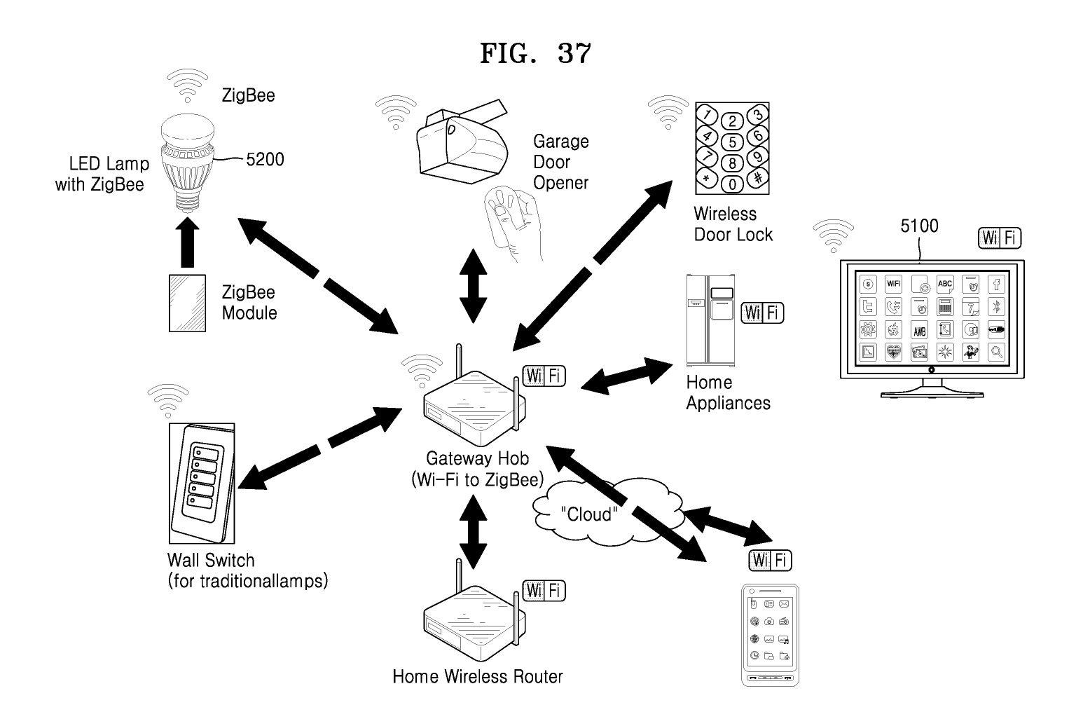

FIG. 37 is a diagram of an example in which an LED lamp 5200 including an LED array unit and an LED module in which an LED package manufactured according to the above example embodiments is arranged, is applied to a home-network.

Specifically, the home-network may automatically control brightness of the LED lamp 5200 using household wireless communications (e.g., ZigBee and WiFi) depending on operation states of a bedroom, a living room, a front door, a storage closet, and household appliances and ambient environments and statuses.

For example, as shown in FIG. 37, the brightness of the LED lamp 5200 including the LED package according to the example embodiment may be automatically controlled by using a gate way and a Zigbee module depending on the type of a TV program viewed on a TV 5100 or the brightness of a screen of the TV 5100. For example, when a drama is shown on the TV 5100 and a cozy atmosphere is needed, a color temperature of the LED lamp 5200 may reduce to about 5000K or lower and the impression of colors may be controlled. In contrast, when a comedy program is shown in a light-hearted atmosphere, a color temperature of the LED lamp 5200 may be increased to about 5000K or higher, and the LED lamp 5200 may be controlled in bluish white colors. The Zigbee module may be unified with an optical sensor to form a module or unified with a light-emitting system.

Visible-light wireless communication technology may wirelessly transmit information by using light having a visible wavelength range, which is visible to the human eyes. The visible-light wireless communication technology may be distinguished from wired optical communication technology and infrared (IR) wireless communication of the related art in that light having a visible wavelength range (i.e., light having a specific visible wavelength range emitted by the LED lamp 5200 according to the present embodiment) is used. Also, the visible-light wireless communication technology may be distinguished from wired optical communication technology of the related art in that a wireless communication environment is used. Also, unlike radio-frequency (RF) wireless communication, the visible-light wireless communication technology may be excellent in convenience and physical security because frequencies may be freely used without regulation or permission. Furthermore, the visible-light wireless communication technology may be unique because a user may see a communication link with the eyes. Most of all, the visible-light wireless communication technology may be characterized as convergence technology by serving as both a light source and a communication device.

In addition, the LED lamp 5200 may be used for an internal light source or an external light source for vehicles. The LED lamp 5200 may be used for an internal light source, such as an interior light, a reading light, or various lights for a gauge board for vehicles. Also, the LED lamp 5200 may be used for an external light source, such as a headlight, a brake light, a direction guide light, a fog light, a running light for vehicles.

An LED lamp 5200 using a particular wavelength range may promote growth of plants, stabilize human feelings, or cure diseases. The LED lamp 5200 may be used as a light source for robots or various mechanical apparatuses. Since the LED lamp 5200 has low power consumption and a long lifetime, illumination systems may be embodied by combining the LED lamp 5200 with an eco-friendly renewable energy power system using solar cells or wind power.

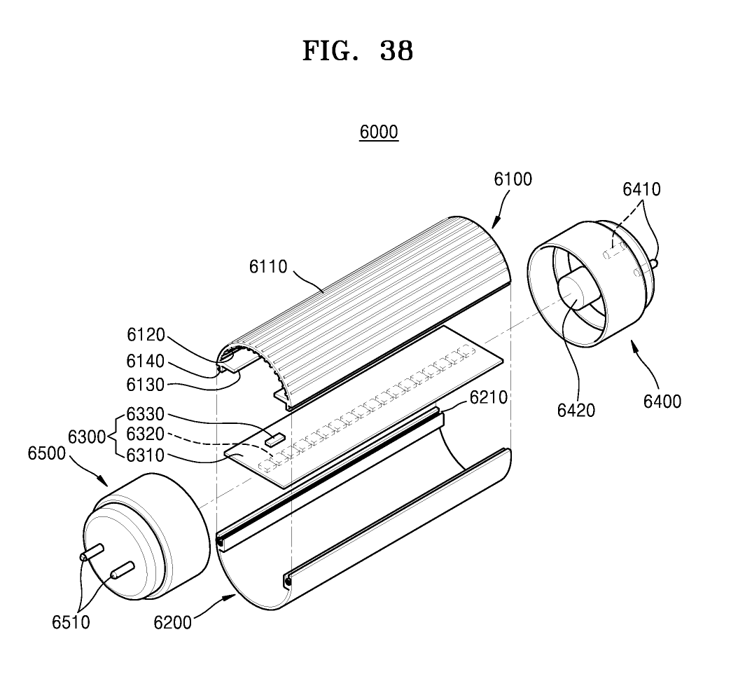

FIG. 38 is an exploded perspective view of a light-emitting system 6000 including an LED array unit and an LED module in which an LED package manufactured according to the above example embodiments is arranged.

Specifically, the light-emitting system (or an illumination system) 6000 may include a heat radiation member 6100, a cover 6200, a light-emitting module 6300, a first socket 6400, and a second socket 6500. A plurality of heat radiation pins (e.g., radiation pins 6110 and 6120) may be formed in the shape of rough portions inside the heat radiation member 6100 and/or an outer surface of the heat radiation member 6100. The heat radiation pins 6110 and 6120 may be designed to have various shapes and intervals. A support 6130 having a protruding shape may be formed inside the heat radiation member 6100. The light-emitting module 6300 may be fixed to the support 6130. Clasps 6140 may be formed at two end portions of the first cover 6110.

Clasp grooves 6210 may be formed in the cover 6200. The clasps 6140 of the heat radiation members 6100 may be hook-combined to the clasp grooves 6210. Positions of the clasp grooves 6210 and the clasp 6140 may be exchanged.

The light-emitting module 6300 may include an LED array unit (or an LED package) according to one of the example embodiments. The light-emitting module 6300 may include a PCB 6310, an LED array 6320, and a communication module 6330. As described above, the communication module 6330 may store rank information of the LED array 6320. Circuit interconnections for operating the LED array 6320 may be formed on the PCB 6310. Also, constituent elements for operating the LED array 6320 may be formed on the PCB 6310.

The first and second sockets 6400 and 6500, which are a pair of sockets, may be combined with two ends of a cylindrical cover unit including the heat radiation member 6100 and the cover 6200. For example, the first socket 6400 may include an electrode terminal 6410 and a power supply device 6420, and the second socket 6500 may include a dummy terminal 6510. The power supply device 6420 may include the LED driver according to one of the above example embodiments. Specifically, the power supply device 6420 may include a variable current output unit and a rank sensing unit, which may respectively serve the same functions as the variable current output unit and the rank sensing unit according to one of the above example embodiments.

Also, an optical sensor module may be embedded in any one of the first socket 6400 or the second socket 6500. For example, an optical sensor module may be embedded in the second socket 6500 in which the dummy terminal 6510 is disposed. In another example, an optical sensor module may be embedded in the first socket 6400 in which the electrode terminal 6410 is disposed.

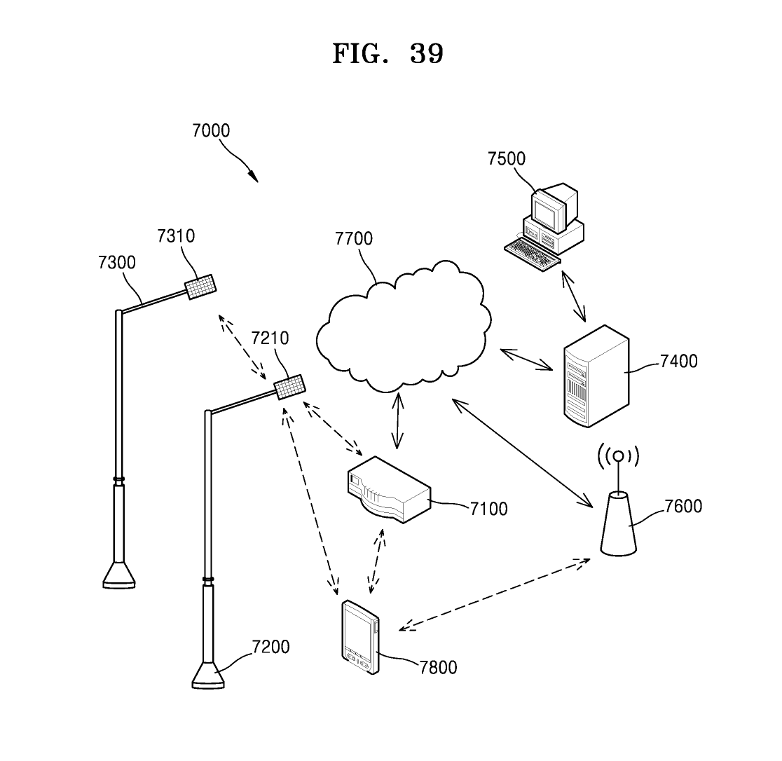

FIG. 39 is a schematic diagram of an example of a network system 7000 to which an LED package as described above is arranged is applied, according to an example embodiment.

Specifically, the network system 7000 according to the present embodiment may include a communication connection device 7100, a plurality of illumination mechanisms (e.g., illumination mechanisms 7200 and 7300) installed at predetermined intervals and connected to the communication connection device 7100 to be capable of communicating with the communication connection device 7100, a server 7400, a computer 7500 configured to manage the server 7400, a communication base station 7600, a communication network 7700 configured to connect the above-described apparatuses capable of communicating with one another, and a mobile device 7800.

The illumination mechanisms 7200 and 7300 installed in an external open space, such as a street or a park, may include smart engines 7210 and 7310, respectively. Each of a plurality of smart engines (e.g., smart engines 7210 and 7310) may include an LED package according to an example embodiment, a sensor configured to collect information regarding circumferential environment except a driver configured to drive the LED package, and a communication module. The communication module may enable the smart engines 7210 and 7310 to communicate with other peripheral apparatuses according to a communication protocol, such as WiFi, Zigbee, or LiFi.

In an example, one smart engine 7210 may be connected to another smart engine 7310 to be capable of communicating with the smart engine 7310. In this case, WiFi extension technology (or WiFi mesh) may be applied to communication between the smart engines 7210 and 7310. At least one smart engine 7210 may be connected by wire or wirelessly to the communication connection device 7100 connected to the communication network 7700. To increase communication efficiency, a plurality of smart engines (e.g., the smart engines 7210 and 7310) may fall into a group and be connected to one communication connection device 7100.

The communication connection device 7100, which is an access point (AP) capable of wired/wireless communication, may mediate between the communication network 7700 and other apparatuses. The communication connection device 7100 may be connected to the communication network 7700 by at least one of wired/wireless communication methods. For example, the communication connection device 7100 may be mechanically contained in any one of the illumination mechanisms 7200 and 7300.

The communication connection device 7100 may be connected to the mobile device 7800 through a communication protocol, such as WiFi. A user of the mobile device 7800 may receive the circumferential environment information, which is collected by the smart engines 7210 and 7310, through the communication connection device 7100 connected to the smart engine 7210 of the illumination mechanism 7200 disposed adjacent thereto. The circumferential environment information may include surrounding traffic information and weather information. The mobile device 7800 may be connected to the communication network 7700 through the communication base station 7600 by using a wireless cellular communication method, such as 3G or 4G.

The server 7400 connected to the communication network 7700 may receive information collected by the smart engines 7210 and 7310 mounted on the illumination mechanisms 7200 and 7300 and simultaneously, monitor operation states of the illumination mechanisms 7200 and 7300. To manage the illumination mechanisms 7200 and 7300 based on monitoring results of the operation states of the illumination mechanisms 7200 and 7300, the server 7400 may be connected to the computer 7500 configured to provide a management system. The computer 7500 may execute software capable of monitoring and managing the operation states of the illumination mechanisms 7200 and 7300, specifically, the smart engines 7210 and 7310.

The foregoing example embodiments have been described with respect to only to manufacturing an LED package; however, the inventive concept is not limited thereto. According to another example embodiment, the above-described method of manufacturing an LED package may apply to various different types of semiconductor device package or integrated circuit chips such as complementary metal-oxide-semiconductor (CMOS) sensors.

While the inventive concept has been particularly shown and described with reference to example embodiments thereof, it will be understood that various changes in form and details may be made therein without departing from the spirit and scope of the following claims.

What is claimed is:

1. A method of manufacturing a light-emitting diode (LED) package, the method comprising:
preparing a support structure on which a plurality of LED chips, each of which includes a semiconductor stack structure, and a light-transmissive material layer covering the plurality of LED chips are formed;
mounting the support structure on a cutting stage; and
cutting the light-transmissive material layer, the semiconductor stack structure, and the support structure between the plurality of LED chips, by using a cutting device having a pattern blade on the cutting stage to singulate each of the LED packages.

2. The method of claim 1, wherein the support structure is a resin substrate.

3. The method of claim 1, wherein the light-transmissive material layer comprises at least one of a wavelength conversion layer and a lens layer.

4. The method of claim 1, wherein each of the LED packages is a chip scale package (CSP).

5. The method of claim 1, wherein the pattern blade comprises a plurality of blades which are patterned in at least one of a widthwise direction and a lengthwise direction with respect to a top surface of the support substrate.

6. The method of claim 1, wherein the pattern blade comprises a plurality of line blades which are patterned in at least one of a widthwise direction and a lengthwise direction with respect to a top surface of the support substrate.

7. The method of claim 1, wherein the pattern blade comprises a plurality of grating blades which are patterned in at least one of a widthwise direction and a lengthwise direction with respect to a top surface of the support substrate.

8. The method of claim 1, wherein the pattern blade comprises a plurality of ring blades which are patterned in at least one of a widthwise direction and a lengthwise direction with respect to a top surface of the support substrate.

9. The method of claim 1, wherein a sectional shape of each of the blades included in the pattern blade is a triangular shape, a square shape, or an elliptical shape.

10. A method of manufacturing a light-emitting diode (LED) package, the method comprising:
mounting a stack of a support structure, a plurality of LED chips disposed on the support structure and a light-transmissive material layer covering the plurality of LED chips, on a cutting stage; and
cutting the stack between the plurality of LED chips, by using a cutting device having a pattern blade on the cutting stage to singulate each of the LED packages.

11. The method of claim 10, wherein the support structure comprises a resin and a circuit pattern is formed on the support structure.

12. The method of claim 10, further comprising:
preparing the plurality of LED chips; and
forming the light-transmissive material layer on the LED chips.

13. The method of claim 10, further comprising adhering an adhesive tape to a bottom surface of the support structure,
wherein the support structure to which the adhesive tape is adhered is mounted on the cutting stage.

14. The method of claim 10, wherein the pattern blade comprises line blades or grating blades which are patterned in at least one of a widthwise direction and a lengthwise direction with respect to a top surface of the support structure,
wherein the line blades and grating blades apply force to the light-transmissive material layer and the support structure in a direction perpendicular to the top surface of the support structure, and cut the light-transmissive material layer and the support structure.

15. The method of claim 10, wherein the pattern blade comprises a plurality of ring blades which are patterned in at least one of a widthwise direction and a lengthwise direction with respect to a top surface of the support structure,
wherein the ring blades apply force to the light-transmissive material layer and the support structure in directions parallel to and perpendicular to the top surface of the support structure and cut the light-transmissive material layer and the support structure.

16. A method of manufacturing a semiconductor device package, the method comprising:
mounting a stack of a support structure, a semiconductor structure and an upper layer, which are stacked in this order, on a cutting stage; and
cutting the stack by using a cutting device having a pattern blade on the cutting stage, to singulate a plurality of semiconductor device packages at the same time.

17. The method of claim 16, wherein the cutting the stack comprises applying force in a direction perpendicular to the stack from a top surface of the upper layer.

18. The method of claim 17, wherein the applying force comprises applying force on boundaries of the plurality of semiconductor packages.

19. The method of claim 17, wherein the pattern blade comprises a plurality of blades which are patterned in at least one of a widthwise direction and a lengthwise direction with respect to a top surface of the support substrate.

20. The method of claim 17, wherein the pattern blade comprises a plurality of grating blades which are patterned in at least one of a widthwise direction and a lengthwise direction with respect to a top surface of the support substrate.
